(19) United States
(12) Patent Application Publication
(10) Pub. No.: US 2010/0320542 A1
(43) Pub. Date: Dec. 23, 2010

(54) SEMICONDUCTOR DEVICE AND MANUFACTURING METHOD THEREOF

(75) Inventors: Takaaki Kawahara, Kanagawa (JP); Shinsuke Sakashita, Kanagawa (JP); Masaru Kadoshima, Kanagawa (JP)

Correspondence Address: MCDERMOTT WILL & EMERY LLP, 600 13TH STREET, N.W., WASHINGTON, DC, 20005-3096, US

(73) Assignee: RENESAS ELECTRONICS CORPORATION

(21) Appl. No.: 12/782,457

(22) Filed: May 18, 2010

(30) Foreign Application Priority Data
Jun. 17, 2009 (JP) 2009-144512

(51) Int. Cl. H01L 27/092; H01L 21/8238

(52) U.S. Cl. 257/369; 438/591; 438/216; 257/E21.639; 257/E27.062

(57) ABSTRACT

To improve the performance of a CMISFET having a high-k gate insulating film and a metal gate electrode. An n-channel MISFET has, over the surface of a p-type well of a semiconductor substrate, a gate electrode formed via a first Hf-containing insulating film serving as a gate insulating film, while a p-channel MISFET has, over the surface of an n-type well, another gate electrode formed via a second Hf-containing insulating film serving as a gate insulating film. These gate electrodes have a stack structure of a metal film and a silicon film thereover. The first Hf-containing insulating film is an insulating material film comprised of Hf, a rare earth element, Si, O, and N or comprised of Hf, a rare earth element, Si, and O, while the second Hf-containing insulating film is an insulating material film comprised of Hf, Al, O, and N or comprised of Hf, Al, and O.

### CROSS-REFERENCE TO RELATED APPLICATIONS

The disclosure of Japanese Patent Application No. 2009-144512 filed on Jun. 17, 2009 including the specification, drawings and abstract is incorporated herein by reference in its entirety.

### BACKGROUND OF THE INVENTION

The present invention relates to a semiconductor device and a manufacturing method thereof, particularly to a technology effective when applied to a semiconductor device equipped with a CMISFET having a high-dielectric-constant gate insulating film and a metal gate electrode and a manufacturing method of the semiconductor device.

A MISFET (metal insulator semiconductor field effect transistor) can be formed by forming a gate insulating film over a semiconductor substrate, forming a gate electrode over the gate insulating film, and forming source/drain regions by ion implantation or the like.

In a CMISFET (complementary MISFET), in order to reduce the threshold voltage of both an n-channel MISFET and a p-channel MISFET, gate electrodes of them are formed respectively by using materials different in work function (Fermi level in the case of polysilicon). In short, a dual gate structure is formed. The threshold voltage is reduced by introducing an n type impurity and a p type impurity into polysilicon films forming the n-channel MISFET and the p-channel MISFET, respectively, thereby approximating the work function (Fermi level) of a gate electrode material of the n-channel MISFET to the conduction band of silicon and the work function (Fermi level) of a gate electrode material of the p-channel MISFET to the valence band of silicon.

With miniaturization of CMISFET devices in recent years, a gate insulating film becomes thinner and it has become impossible to neglect the influence of depletion of a gate electrode for which a polysilicon film has been used. With a view to overcoming this problem, there is a technology of suppressing a depletion phenomenon of a gate electrode by using, as the gate electrode, a metal gate electrode.

Further, the gate insulating film becomes thinner due to miniaturization of CMISFET devices and use of a thin silicon oxide film as the gate insulating film inevitably causes a tunnel current, that is, electrons flowing in the channel of MISFET tunnel through a barrier formed by a silicon oxide film and reaches the gate electrode. There is therefore disclosed a technology of using, for the gate insulating film, a material having a higher dielectric constant (high-dielectric-constant material) than that of the silicon oxide film to increase a physical film thickness without changing the capacitance and thereby reduce a leakage current.

Japanese Unexamined Patent Publication No. 2004-296536 (Patent Document 1) describes a technology of forming a high-dielectric-constant gate insulating film having a structure obtained by stacking a nitrogen rich layer, a nitrogen poor layer, and a nitrogen rich layer over a silicon substrate in the order of mention.

Japanese Unexamined Patent Publication No. 2005-64317 (Patent Document 2) describes a technology of, in a semiconductor device having a gate insulating film formed over a silicon substrate and a gate electrode formed over the gate insulating film, forming the gate insulating film from a first insulating film, a second insulating film formed over the first insulating film, and a metal oxynitride film formed over the second insulating film and employing, as the metal oxynitride film, either one of an AlON film or a HfON film.

Japanese Unexamined Patent Publication No. 2008-306051 (Patent Document 3) describes a technology for a CMISFET having symmetrical flat band voltages, the same gate electrode material, and a high-dielectric-constant dielectric layer.

Non-patent Document 1 describes a technology for an La₂O₃ cap layer over a high dielectric constant film.

### [Patent Document]

### [Patent Document 1] Japanese Unexamined Patent Publication No. 2004-296536

### [Patent Document 2] Japanese Unexamined Patent Publication No. 2005-64317

### [Patent Document 3] Japanese Unexamined Patent Publication No. 2008-306051

### [Non-patent Document]

### [Non-patent Document 1]

T. Kawahara and 12 others, “Application of PVD-La₂O₃ with A-scale Controllability to Metal/Cap/High-k Gate Stacks”, [IWDTF-08], (Japan), 2008, p. 37-38

### SUMMARY OF THE INVENTION

The investigation by the present inventors has revealed the following findings.

Using a metal gate electrode can dissolve the problem of depletion of a gate electrode, but compared with using a polysilicon gate electrode, it inevitably raises an absolute value of a threshold voltage of both an n-channel MISFET and a p-channel MISFET. It is therefore desired to reduce the threshold value (reduce the absolute value of the threshold voltage) when a metal gate electrode is employed. When the re-channel MISFET and the p-channel MISFET respectively have metal gate electrodes of the same configuration and gate insulating films of the same configuration, reduction in the threshold value of either one of the n-channel MISFET and the p-channel MISFET inevitably causes an increase in the threshold value of the other one.

It is therefore desired to independently control the threshold voltages of the n-channel MISFET and the p-channel MISFET. In order to realize it, it is presumed to select different materials for the metal gate electrode of the re-channel MISFET and the metal gate electrode of the p-channel MISFET. Using different materials for the metal gate electrode of the n-channel MISFET and the metal gate electrode of the p-channel MISFET makes a manufacturing step (gate electrode forming step) of a semiconductor device cumbersome and complicated and causes a decrease in throughput of a semiconductor device or an increase in the manufacturing cost of the semiconductor device.

It is therefore effective to select different insulating materials for the gate insulating film of the n-channel MISFET and the gate insulating film of the p-channel MISFET in order to independently control the threshold voltages of the n-channel MISFET and p-channel MISFET.

As a high dielectric constant film (high-k film) for a gate insulating film, an Hf-based gate insulating film which is a high dielectric constant film containing Hf is excellent. Introduction of a rare earth element (particularly preferably, lanthanum) into the Hf-based gate insulating film of the re-channel MISFET can reduce the threshold value of the n-channel MISFET. Introduction of aluminum into the Hf-based gate insulating film of the p-channel MISFET can, on the other hand, reduce the threshold value of the p-channel MISFET. It is therefore possible to reduce both of the threshold values of the n-channel MISFET and the p-channel MISFET by selectively introducing a rare earth element (particularly, lanthanum) into the Hf-based gate insulating film of the n-channel MISFET and selectively introducing aluminum into the Hf-based gate insulating film of the p-channel MISFET.

Investigation by the present inventors has however revealed that only selective introduction of a rare earth element into the Hf-based gate insulating film of the n-channel MISFET and selective introduction of aluminum into the Hf-based gate insulating film of the p-channel MISFET cause a large difference in the EOT (equivalent oxide thickness) of the gate insulating film between the n-channel MISFET and the p-channel MISFET. For example, compared with an HfLaSiON film obtained by selectively introducing La into an HfSiON film, an HfAlSiON film obtained by selectively introducing Al into an HfSiON film has inevitably a large EOT because its dielectric constant is small.

Since an Hf-based gate insulating film containing no Si such as an HfON film has a higher dielectric constant than an Hf-based gate insulating film containing Si such as an HfSiON film, use of an Hf-based gate insulating film containing no Si is effective in order to reduce the EOT of the Hf-based gate insulating film. The investigation by the present inventors has however revealed that when a rare earth element such as La is introduced into an Hf-based gate insulating film containing no Si to convert it into an HfLaON film, there is a risk of inconvenience due to a weak binding power between La and Hf. For example, upon dry etching for processing a gate electrode or wet etching of a gate insulating film not covered with a gate electrode which will be conducted later, there is a risk of inconvenience such as generation of a foreign matter or retreat of the HfLaON film, which is a gate insulating film, from the side surface of the gate electrode due to easy separation or elution of LaO from the HfLaON film. This may deteriorate the performance of the resulting semiconductor device. In addition, for the reduction of a threshold value by introducing La into the Hf-based gate insulating film of an n-channel MISFET, La is preferably diffused sufficiently in the Hf-based gate insulating film in a substrate direction. In the HfLaON film, compared with in the HfLaSiON film, La is not diffused easily due to a weak binding power between La and Hf. A threshold value reducing effect produced by introduction of La is therefore smaller in the n-channel MISFET using an HfLaON film as the gate insulating film than in the n-channel MISFET using an HfLaSiON film as the gate insulating film. As a result, an absolute value of the threshold voltage becomes greater. This also deteriorates the performance of the semiconductor device.

An object of the present invention is to provide a technology capable of improving the performance of a semiconductor device equipped with a CMISFET having a high dielectric constant gate insulating film and a metal gate electrode.

The above-described and the other objects and novel features of the invention will be apparent from the description herein and accompanying drawings.

Typical inventions, among the inventions disclosed herein, will next be described briefly.

A semiconductor device according to a typical embodiment is equipped with an n-channel first MISFET and a p-channel second MISFET. The first MISFET has a first metal gate electrode formed over a semiconductor substrate via a first gate insulating film, while the second MISFET has a second metal gate electrode formed over the semiconductor substrate via a second gate insulating film. The first gate insulating film is made of an insulating material containing hafnium, a rare earth element, silicon, and oxygen as main components and the second gate insulating film contains hafnium, aluminum, and oxygen as main components but not containing silicon as a main component.

A manufacturing method of a semiconductor device according to a typical embodiment is a manufacturing method of a semiconductor device having an n-channel first MISFET in a first region of a semiconductor substrate and a p-channel second MISFET in a second region of the semiconductor substrate. First, an Hf-containing insulating film for a gate insulating film of the first and second MISFETs is formed in the first region and the second region; an Al-containing film is formed over the Hf-containing insulating film in the second region; and a rare-earth-containing film containing a rare earth element and silicon is formed over the Hf-containing insulating film in the first region. Heat treatment is then performed to cause a reaction between the Hf-containing insulating film and the rare-earth-containing film in the first region and a reaction between the Hf-containing insulating film and the Al-containing film in the second region.

Another manufacturing method of a semiconductor device according to a typical embodiment is a manufacturing method of a semiconductor device having an n-channel first MISFET in a first region of a semiconductor substrate and a p-channel second MISFET in a second region of the semiconductor substrate. First, an HF-containing insulating film for the gate insulating film of the first and second MISFETs is formed in the first region and the second region of the semiconductor substrate; an Al-containing film is formed over the Hf-containing insulating film in the second region; and a silicon-containing layer made of silicon or silicon oxide is formed over the Hf-containing insulating film in the first region. Heat treatment is then performed to cause a reaction between the Hf-containing insulating film and the silicon-containing layer in the first region and a reaction between the Hf-containing insulating film and the Al-containing film in the second region. After formation of a rare-earth-containing film containing a rare earth element over the Hf-containing insulating film in the first region, heat treatment is performed to cause a reaction between the Hf-containing insulating film and the rare-earth-containing film in the first region.

An advantage available by the typical invention, among the inventions disclosed herein, will next be described briefly.

The typical embodiment of the invention enables to improve the performance of a semiconductor device.

### BRIEF DESCRIPTION OF THE DRAWINGS

FIG. 1 is a fragmentary cross-sectional view of a semiconductor device according to one embodiment of the invention;

FIG. 2 is a manufacturing process flow chart showing some manufacturing steps of the semiconductor device according to the embodiment of the invention;

FIG. 3 is a fragmentary cross-sectional view of the semiconductor device according to the embodiment of the invention during a manufacturing step thereof;

FIG. 4 is a fragmentary cross-sectional view of the semiconductor device during a manufacturing step thereof following that of FIG. 3;

FIG. 5 is a fragmentary cross-sectional view of the semiconductor device during a manufacturing step thereof following that of FIG. 4;

FIG. 6 is a fragmentary cross-sectional view of the semiconductor device during a manufacturing step thereof following that of FIG. 5;

FIG. 7 is a fragmentary cross-sectional view of the semiconductor device during a manufacturing step thereof following that of FIG. 6;

FIG. 8 is a fragmentary cross-sectional view of the semiconductor device during a manufacturing step thereof following that of FIG. 7;

FIG. 9 is a fragmentary cross-sectional view of the semiconductor device during a manufacturing step thereof following that of FIG. 8;

FIG. 10 is a fragmentary cross-sectional view of the semiconductor device during a manufacturing step thereof following that of FIG. 9;

FIG. 11 is a fragmentary cross-sectional view of the semiconductor device during a manufacturing step thereof following that of FIG. 10;

FIG. 12 is a fragmentary cross-sectional view of the semiconductor device during a manufacturing step thereof following that of FIG. 11;

FIG. 13 is a fragmentary cross-sectional view of the semiconductor device during a manufacturing step thereof following that of FIG. 12;

FIG. 14 is a fragmentary cross-sectional view of the semiconductor device during a manufacturing step thereof following that of FIG. 13;

FIG. 15 is a fragmentary cross-sectional view of the semiconductor device during a manufacturing step thereof following that of FIG. 14;

FIG. 16 is a fragmentary cross-sectional view of the semiconductor device during a manufacturing step thereof following that of FIG. 15;

FIG. 17 is a fragmentary cross-sectional view of a semiconductor device according to a first comparative example investigated by the present inventors;

FIG. 18 is a fragmentary cross-sectional view of a semiconductor device according to a second comparative example investigated by the present inventors;

FIG. 19 is a manufacturing process flow chart showing some manufacturing steps of a semiconductor device according to another embodiment of the invention;

FIG. 20 is a fragmentary cross-sectional view of the semiconductor device according to the other embodiment of the invention during a manufacturing step;

FIG. 21 is a fragmentary cross-sectional view of the semiconductor device during a manufacturing step thereof following that of FIG. 20;

FIG. 22 is a fragmentary cross-sectional view of the semiconductor device during a manufacturing step thereof following that of FIG. 21;

FIG. 23 is a fragmentary cross-sectional view of the semiconductor device during a manufacturing step thereof following that of FIG. 22;

FIG. 24 is a fragmentary cross-sectional view of the semiconductor device during a manufacturing step thereof following that of FIG. 23;

FIG. 25 is a fragmentary cross-sectional view of the semiconductor device during a manufacturing step thereof following that of FIG. 24;

FIG. 26 is a manufacturing process flow chart showing some manufacturing steps of a semiconductor device according to a further embodiment of the invention;

FIG. 27 is a fragmentary cross-sectional view of the semiconductor device according to the further embodiment of the invention during a manufacturing step;

FIG. 28 is a fragmentary cross-sectional view of the semiconductor device during a manufacturing step thereof following that of FIG. 27;

FIG. 29 is a fragmentary cross-sectional view of the semiconductor device during a manufacturing step thereof following that of FIG. 28;

FIG. 30 is a fragmentary cross-sectional view of the semiconductor device during a manufacturing step thereof following that of FIG. 29;

FIG. 31 is a fragmentary cross-sectional view of the semiconductor device during a manufacturing step thereof following that of FIG. 30; and

FIG. 32 is a fragmentary cross-sectional view of the semiconductor device during a manufacturing step thereof following that of FIG. 31.

### DETAILED DESCRIPTION OF THE PREFERRED EMBODIMENTS

In the below-described embodiments, a description will be made after they are divided in plural sections or in plural embodiments if necessary for convenience's sake. These plural sections or embodiments are not independent of each other, but in a relation such that one is a modification example, details, or complementary description of a part or whole of the other one unless otherwise specifically indicated. In the below-described embodiments, when a reference is made to the number of elements (including the number, value, amount, and range), the number of elements is not limited to a specific number but can be greater than or less than the specific number unless otherwise specifically indicated or principally apparent that the number is limited to the specific number. Moreover in the below-described embodiments, it is needless to say that the constituent elements (including element steps) are not always essential unless otherwise specifically indicated or principally apparent that they are essential. Similarly, in the below-described embodiments, when a reference is made to the shape, positional relationship, or the like of the constituent elements, that substantially analogous or similar to it is also embraced unless otherwise specifically indicated or different in principle. This also applies to the above-described value and range.

The embodiments of the invention will hereinafter be described in detail based on some drawings. In all the drawings for describing the below-described embodiments, members having like function will be identified by like reference numerals and overlapping descriptions will be omitted.

In the drawings used in the embodiments, some cross-sectional views are not hatched in order to facilitate viewing of them. On the other hand, some plan views may be hatched to facilitate viewing of them.

### Embodiment 1

The semiconductor device according to the present embodiment will next be described based on some drawings.

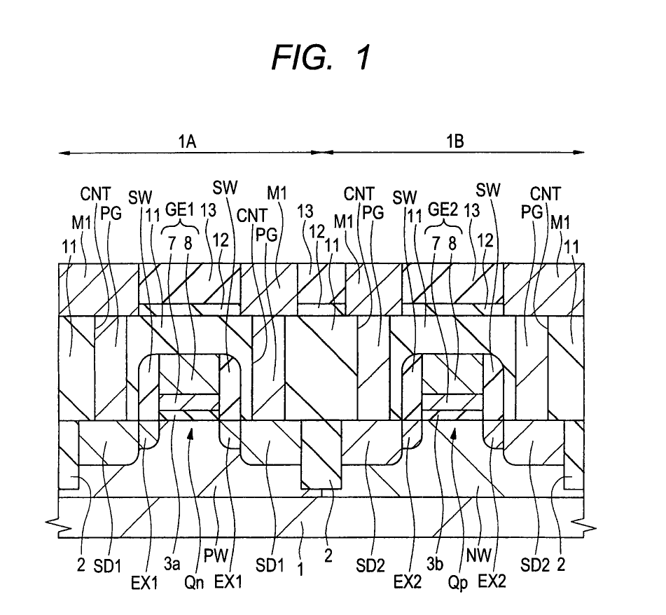

FIG. 1 is a fragmentary cross-sectional view of a semiconductor device according to one embodiment of the invention, that is, a semiconductor device having a CMISFET (complementary metal insulator semiconductor field effect transistor).

As illustrated in FIG. 1, the semiconductor device according to the present embodiment has an n-channel MISFET (metal insulator semiconductor field effect transistor: MIS field effect transistor) Qn formed in an nMIS formation region 1A of a semiconductor substrate 1 and a p-channel MISFET Qp formed in a pMIS formation region 1B of the semiconductor substrate 1.

Described specifically, the semiconductor substrate 1 comprised of, for example, a p type single crystal silicon has an nMIS formation region (first region) 1A and a pMIS formation region (second region) 1B which are electrically isolated from each other, defined by an element isolation region 2. A p-type well PW is formed in the semiconductor substrate 1 of the nMIS formation region 1A, while an n-type well NW is formed in the semiconductor substrate 1 of the pMIS formation region 1B. Over the surface of the p-type well PW in the nMIS formation region 1A, a gate electrode (first metal gate electrode, a first gate electrode) GE1 of an n-channel MISFET (first MISFET) Qn is formed via an Hf-containing insulating film (first gate insulating film) 3a functioning as a gate insulating film of the n-channel MISFET Qn. On the other hand, over the surface of the n-type well NW in the pMIS formation region 1B, a gate electrode (a second metal gate electrode, a second gate electrode) GE2 of a p-channel MISFET (second MISFET) Qp is formed via an Hf-containing insulating film (second gate insulating film) 3b functioning as the gate insulating film of the p-channel MISFET Qp. The Hf-containing insulating film 3a and the Hf-containing insulating film 3b can be formed directly on the surface (silicon surface) of the semiconductor substrate 1 (p-type well PW and n-type well NW). Alternatively, a thin silicon oxide film (not illustrated) may be placed at the interface between the Hf-containing insulating film 3a or the Hf-containing insulating film 3b and the semiconductor substrate 1 (p-type well PW and n-type well NW) as an interface layer. As the interface layer, a silicon oxynitride film may be used instead of the silicon oxide film.

Each of the gate electrodes GE1 and GE2 is made of a film stack of a metal film (metal gate film) 7 contiguous to the gate insulating film (the Hf-containing insulating film 3a in the nMIS formation region 1A and the Hf-containing insulating film 3b in the pMIS formation region 1B) and a silicon film 8 overlying the metal film 7. The metal film 7 is preferably a titanium nitride (TiN) film, a tantalum nitride (TaN) film, or a tantalum carbide (TaC) film, most preferably a titanium nitride (TiN) film.

The Hf-containing insulating film 3a serving as the gate insulating film of the n-channel MISFET Qn is made of an insulating material containing, as main components thereof, Hf (hafnium), a rare earth element, Si (silicon), and O (oxygen). The Hf-containing insulating film 3a containing N (nitrogen) further is more preferred for reducing a leakage current further. As the rare earth element contained in the Hf-containing insulating film 3a is particularly preferably La (lanthanum). When the rare earth element contained in the Hf-containing insulating film 3a is Ln, the Hf-containing insulating film 3a is preferably an HfLnSiON film (an HfLaSiON film in the case where Ln=La) or an HfLnSiO film (an HfLaSiO film in the case where Ln=La).

The Hf-containing insulating film 3b functioning as the gate insulating film of the p-channel MISFET Qp is made of an insulating material containing, as main components thereof, Hf (hafnium), Al (aluminum), and O (oxygen). The Hf-containing insulating film 3b containing N (nitrogen) further is more preferred for reducing a leakage current further. Accordingly, the Hf-containing insulating film 3b is preferably an HfAlON film or an HfAlO film.

The HfLnSiON film is an insulating material film made of hafnium (Hf), a rare earth element (Ln), and silicon (Si), oxygen (O), and nitrogen (N); the HfLnSiO film is an insulating material film made of hafnium (Hf), a rare earth element (Ln), silicon (Si), and oxygen (O); the HfLaSiON film is an insulating material film made of hafnium (Hf), lanthanum (La), silicon (Si), oxygen (O), and nitrogen (N); and the HfLaSiO film is an insulating material film made of hafnium (Hf), lanthanum (La), silicon (Si), and oxygen (O). The HfAlON film is an insulating material film made of hafnium (Hf), aluminum (Al), oxygen (O), and nitrogen (N), while the HfAlO film is an insulating material film made of hafnium (Hf), aluminum (Al), and oxygen (O).

The term “HfLnSiON film” as used herein is not limited to a film having Hf, Ln, Si, O, and N at an atomic ratio of 1:1:1:1:1. This also applies to the above-described HfLnSiO film, HfLaSiON film, HfLaSiO film, HfAlON film, and HfAlO film and also an HfON film, HfO film, HfSiON film, HfSiO film, LnSiO film, LaSiO film, AlON film, AlO film, HfAlSiON film, and HfLaON film which will be described later.

The Hf-containing insulating film 3a contains a rare earth element (particularly preferably, La) effective for reducing the threshold value of the n-channel MISFET Qn, while the Hf-containing insulating film 3b contains Al effective for reducing the threshold value of the p-channel MISFET Qp. What is contrasting between the Hf-containing insulating film 3a and the Hf-containing insulating film 3b is that the former one contains, as a main component thereof, Si (silicon), while the latter one does not contain, as a main component thereof, Si (silicon). In addition, the Hf-containing insulating film 3a is preferably free from Al and the Hf-containing insulating film 3b is preferably free from a rare earth element (particularly, La). The Hf-containing insulating film 3a and the Hf-containing insulating film 3b are each an insulating film having a higher permittivity (dielectric constant) than silicon oxide, so-called high-k film (high dielectric constant film).

Although the Hf-containing insulating film 3b and an Hf-containing insulating film 3 and an Al-containing film 4 which will be described later contain, as one of the characteristics thereof, no Si (silicon), they may contain Si as a trace impurity contained involuntarily after completion of all the treatments in the manufacturing flow of a CMISFET device.

In the p-type well PW in the nMIS formation region 1A, n⁻ type semiconductor regions (extensions region, LDD regions) EX1 and n⁺ type semiconductor regions (source/drain regions) SD1 having a higher impurity concentration than the n⁻ type semiconductor regions EX1 are formed as source/drain regions of an LDD (lightly doped drain) structure of the n-channel MISFET Qn. On the other hand, in the n-type well NW in the pMIS formation region 1B, p⁻ type semiconductor regions (extension regions, LDD regions) EX2 and p⁺ type semiconductor regions (source/drain regions) SD2 having a higher concentration than the p⁻ type semiconductor regions are formed as source/drain regions of an LDD structure of the p-channel MISFET Qp.

The gate electrodes GE1 and GE2 each have, on the side surfaces thereof, sidewalls (sidewall spacers, sidewall insulating films) SW made of an insulator. In the nMIS formation region 1A, the n⁻ type semiconductor regions EX1 are formed in alignment with the gate electrode GE1 and the n⁺ type semiconductor regions SD1 are formed in alignment with the sidewalls W formed over the side surfaces of the gate electrode GE1. In the pMIS formation region 1B, the p⁻ type semiconductor regions EX2 are formed in alignment with the gate electrode GE2 and the p⁺ type semiconductor regions SD2 are formed in alignment with the sidewalls SW formed over the side surfaces of the gate electrode GE2.

An insulating film 11 is formed as an interlayer insulating film over the main surface of the semiconductor substrate 1 so as to cover the n-channel MISFET Qn and the p-channel MISFET Qp. A contact hole CNT is formed in this insulating film 11 and the contact hole CNT is filled with a plug PG. Over the insulating film 11 embedded with the plug PG, a film stack obtained by stacking a stopper insulating film 12 and an insulating film 13 one after another in the order of mention is formed. In an interconnect trench formed in the film stack, an interconnect M1 is formed (embedded). The interconnect M1 is electrically coupled, via the plug PG, to the n⁺ type semiconductor regions SD1, the p⁺ type semiconductor regions SD2, and the like for the source/drain of the n-channel MISFET Qn and the p-channel MISFET Qp. A multilayer interconnect structure is formed thereover but it is not illustrated here and description on it is also omitted.

Manufacturing steps of the semiconductor device of the present embodiment as illustrated in FIG. 1 will next be described referring to some drawings.

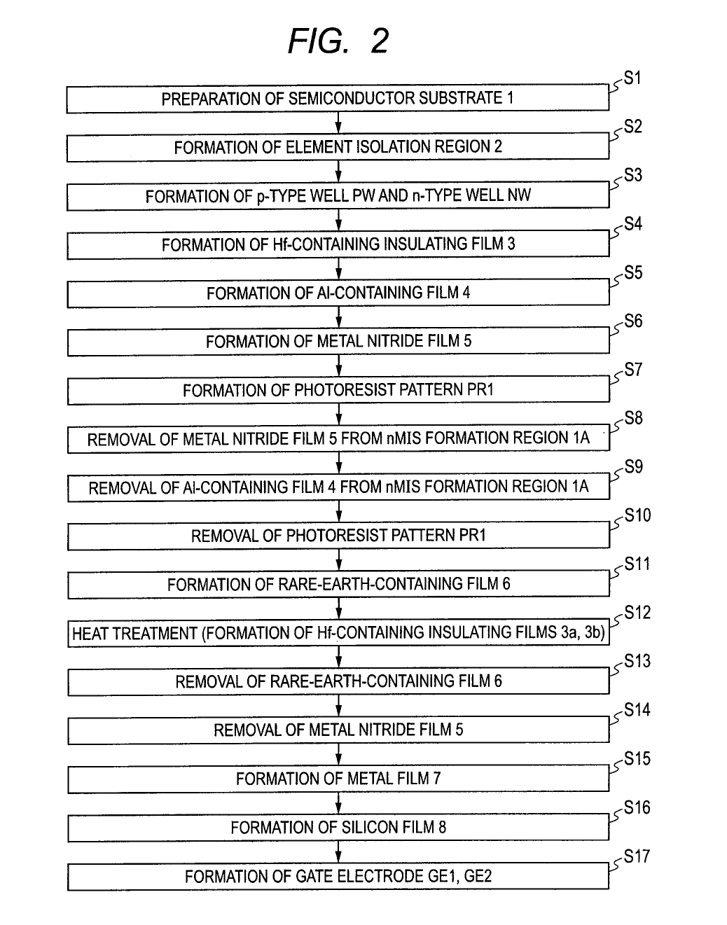

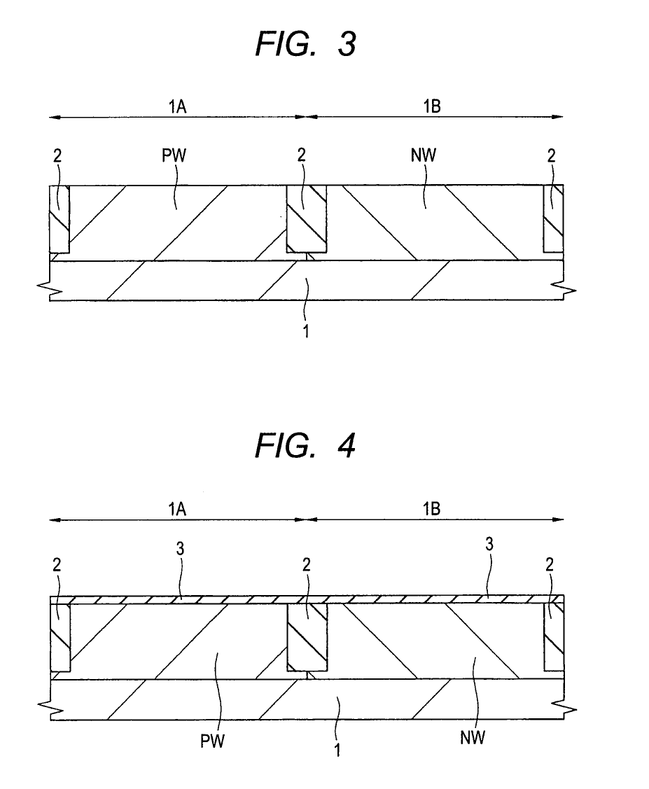

FIG. 2 is a manufacturing process flow chart showing some manufacturing steps of the semiconductor device according to the present embodiment, that is, a semiconductor device having a CMISFET. FIGS. 3 to 16 are each a fragmentary cross-sectional view of the semiconductor device according to the present embodiment, that is, a semiconductor device having a CMISFET.

First, as illustrated in FIG. 3, a semiconductor substrate (semiconductor wafer) 1 made of, for example, a p type single crystal silicon having a specific resistance of from about 1 Ocm to 10 Ocm is prepared (Step S1 of FIG. 2). The semiconductor substrate 1 over which the semiconductor device of the present embodiment is to be formed has an nMIS formation region 1A in which an n-channel MISFET is to be formed and a pMIS formation region 1B in which a p channel MISFET is to be formed. Then, an element isolation region 2 is formed in the main surface of the semiconductor substrate 1 (Step S2 of FIG. 2). The element isolation region 2 is made of an insulator such as silicon oxide and is formed, for example, by an STI (shallow trench isolation) method. For example, the element isolation region 2 can be formed using an insulating film embedded in a trench (element isolation trench) formed in the semiconductor substrate 1.

Then, a p-type well PW is formed in a region (nMIS formation region 1A) of the semiconductor substrate 1 in which the n-channel MISFET is to be formed and an n-type well NW is formed in a region (pMIS formation region 1B) in which the p-channel MISFET is to be formed (Step S3 of FIG. 2). In Step S3, the p-type well PW is formed by ion implantation of a p type impurity such as boron (B) and the n-type well NW is formed by ion implantation of an n type impurity such as phosphorus (P) or arsenic (As). Before or after the formation of the p-type well PW and the n-type well NW, ion implantation (so-called channel doping ion implantation) for controlling the threshold value of the MISFET which will be formed later may be carried out, if necessary, to the upper-layer portion of the semiconductor substrate 1.

Wet etching with, for example, an aqueous solution of hydrofluoric acid (HF) is then carried out to remove a natural oxide film from the surface of the semiconductor substrate 1, thereby cleaning (washing) the surface of the semiconductor substrate 1. This wet etching exposes the surface (silicon surface) of the semiconductor substrate 1 (p-type well PW and n-type well NW).

Then, as illustrated in FIG. 4, an Hf-containing insulating film (first insulating film) 3 for a gate insulating film is formed over the surface of the semiconductor substrate 1 (that is, the surfaces of the p-type well PW and the n-type well NW) (Step S4 of FIG. 2). Since the Hf-containing insulating film 3 is formed all over the main surface of the semiconductor substrate 1, it is formed in both the nMIS formation region 1A and the pMIS formation region 1B. This Hf-containing insulating film 3 is an insulating film which will be a base for forming the gate insulating film of the n-channel MISFET Qn and the p-channel MISFET Qp.

The Hf-containing insulating film 3 is an insulating film containing Hf and is made of an insulating material containing Hf (hafnium). It contains no Si (silicon), which is one of the characteristics thereof. In short, the Hf-containing insulating film 3 is an insulating film containing Hf but not containing Si. The Hf-containing insulating film 3 is preferably an HfON film (hafnium oxynitride film) or an HfO film (hafnium oxide film, typically an HfO₂ film). Accordingly, the Hf-containing insulating film 3 contains, in addition to hafnium (Hf), oxygen (O). The HfON film (hafnium oxynitride film) is an insulating material film comprised of hafnium (Hf), oxygen (O), and nitrogen (N) and the HfO film (hafnium oxide film) is an insulating material film comprised of hafnium (Hf) and oxygen (O). Since an HfSiON film (hafnium silicon oxynitride film) or an HfSiO film (hafnium silicate film) contains Si, care should be taken so as not to use the HfSiON film or HfSiO film as the Hf-containing insulating film 3.

When the Hf-containing insulating film 3 is an HfON film, it can be formed by depositing an HfO film (typically, HfO₂ film) by using ALD (atomic layer deposition) or CVD (chemical vapor deposition) and then subjecting the resulting HfO film to nitriding treatment such as plasma nitriding treatment to nitride it (to convert the HfO film to an HfON film). After the nitriding treatment, the resulting film may be heat treated in an inert or oxidizing atmosphere.

When the Hf-containing insulating film 3 is an HfO film (typically, HfO₂ film), an HfO film (typically, HfO₂ film) may be deposited by using ALD or CVD and nitriding treatment is not required.

As the Hf-containing insulating film 3, the HfON film (hafnium oxynitride film) is more preferable than the HfO film (hafnium oxide film) from the standpoint of suppressing a leakage current. Using the HfON film (hafnium oxynitride film) as the Hf-containing insulating film 3 enables to reduce a leakage current further. The thickness of the Hf-containing insulating film 3 can be set at, for example, from about 2 nm to 3 nm.

Although the Hf-containing insulating film 3 may be formed directly on the surface (silicon surface) of the semiconductor substrate 1 (the p-type well PW and the n-type well NW), it is more preferred to form, in Step S4, a thin silicon oxide film (not illustrated) as an interface layer over the surface (silicon surface) of the semiconductor substrate 1 (the p-type well PW and the n-type well NW) prior to the formation of the Hf-containing insulating film 3 and then form the Hf-containing insulating film 3 over the resulting silicon oxide film (interface layer). This silicon oxide film is formed in order to improve the driving capacity or reliability by forming an SiO₂/Si structure at the interface between the gate insulating film and the semiconductor substrate, thereby decreasing the number of defects such as traps to a level similar to that of a conventional SiO₂ gate insulating film (gate insulating film made of silicon oxide). The silicon oxide film (interface layer) can be formed by thermal oxidation or the like. Its thickness can be decreased to preferably from 0.3 nm to 1 nm, for example, about 0.6 nm. Instead of the silicon oxide film, a silicon oxynitride film may be formed as the interface layer.

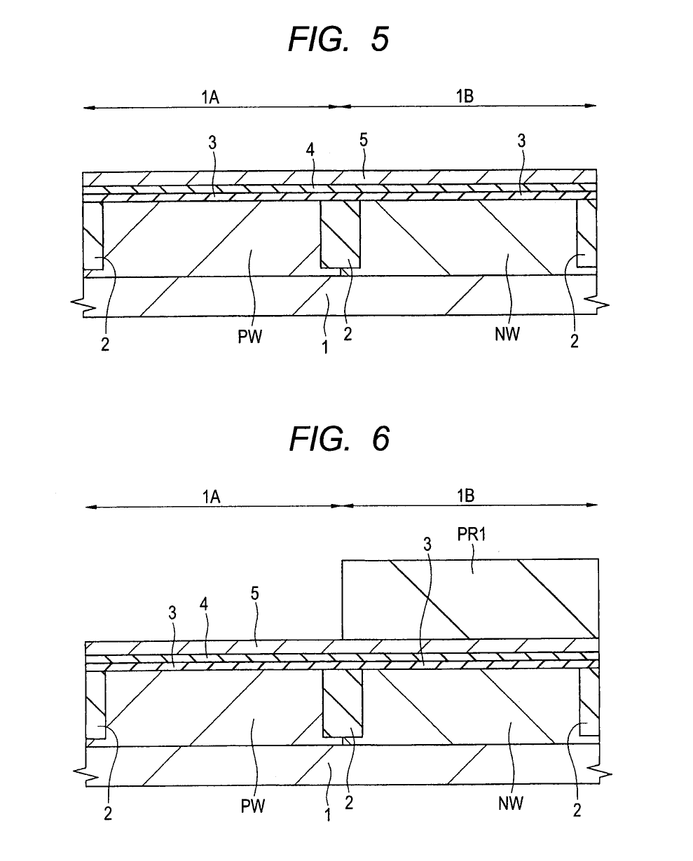

Then, as illustrated in FIG. 5, an Al-containing film (Al-containing layer) 4 is formed over the main surface of the semiconductor substrate 1, that is, over the Hf-containing insulating film 3 (Step S5 of FIG. 2). Since the Al-containing film 4 is formed all over the main surface of the semiconductor substrate 1 in this Step S5, it is formed over the Hf-containing insulating film 3 in both the nMIS formation region 1A and the pMIS formation region 1B.

The Al-containing film 4 is a material film containing Al (aluminum) and is made of a material containing Al (aluminum). It has no Si (silicon), which is one of the characteristics of the film. In short, the Al-containing film 4 is a film containing Al but not containing Si. As the Al-containing film 4, an aluminum oxide film (an AlO film, typically, Al₂O₃ film) is most preferred, but instead, an aluminum oxynitride film (AlON film) or an aluminum film (Al film) can also be used. Since an AlSiO film (aluminum silicate film) or an AlSiON film contains Si, care should be taken so as not to use the AlSiO film or AlSiON film as the Al-containing film 4. The Al-containing film 4 can be formed by sputtering, ALD, or the like method and its thickness can be set at, for example, from about 0.5 nm to 1 nm.

Next, a metal nitride film (mask layer) 5 is formed as a reaction-preventing mask layer over the main surface of the semiconductor substrate 1, that is, over the Al-containing film 4 (Step S6 of FIG. 2). In this step S6, the metal nitride film 5 is formed all over the main surface of the semiconductor substrate 1 so that it is formed over the Al-containing film 4 in both the nMIS formation region 1A and the pMIS formation region 1B.

The metal nitride film 5 is preferably a titanium nitride (TiN) film, a hafnium nitride (HfN) film, or a zirconium nitride (ZrN) film. Of these, a titanium nitride (TiN) film is particularly preferred. The metal nitride film 5 can be formed by sputtering or the like method and the thickness of it can be set at, for example, from about 5 nm to 20 nm.

Then, as illustrated in FIG. 6, a photoresist film is formed by application over the main surface of the semiconductor substrate 1, that is, over the metal nitride film 5. The resulting photoresist film is exposed and developed to form a photoresist pattern (resist pattern) PR1 as a resist pattern (Step S7 of FIG. 2).

The photoresist pattern PR1 is formed over the metal nitride film 5 in the pMIS formation region 1B but is not formed in the nMIS formation region 1A. The metal nitride film 5 in the pMIS formation region 1B is therefore covered with the photoresist pattern PR1, but the metal nitride film 5 in the nMIS formation region 1A is not covered with the photoresist pattern PR1 and is exposed.

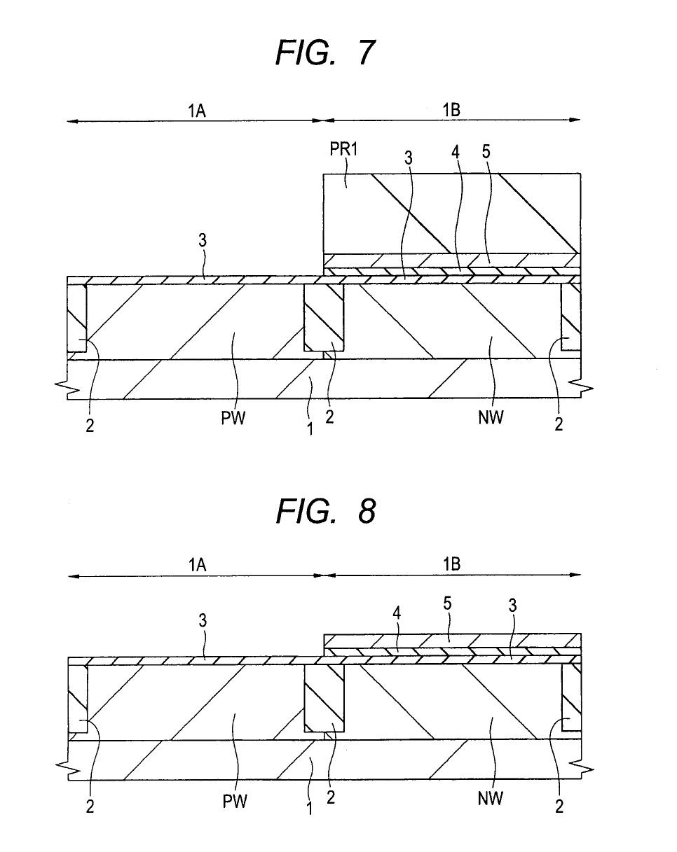

As illustrated in FIG. 7, the metal nitride film 5 is then removed from the nMIS formation region 1A by etching (preferably, wet etching) with the photoresist pattern PR1 as an etching mask (Step S8 of FIG. 2). Next, the Al-containing film 4 is removed from the nMIS formation region 1A by etching (preferably, wet etching) with the photoresist pattern PR1 as an etching mask (Step S9 of FIG. 2).

By these etching steps in Steps S8 and S9, the metal nitride film 5 and the Al-containing film 4 are etched off from the nMIS formation region 1A as illustrated in FIG. 7, but the metal nitride film 5 and the Al-containing film 4 in the pMIS formation region 1B remain without etching because they are covered with the photoresist pattern PR1. By these steps, the Hf-containing insulating film 3 in the nMIS formation region 1A is exposed, while the Hf-containing insulating film 3 in the pMIS formation region 1B continues to be covered with the film stack of the Al-containing film 4 and the metal nitride film 5 (continues to be unexposed).

As illustrated in FIG. 8, the photoresist pattern PR1 is then removed (Step S10 of FIG. 2).

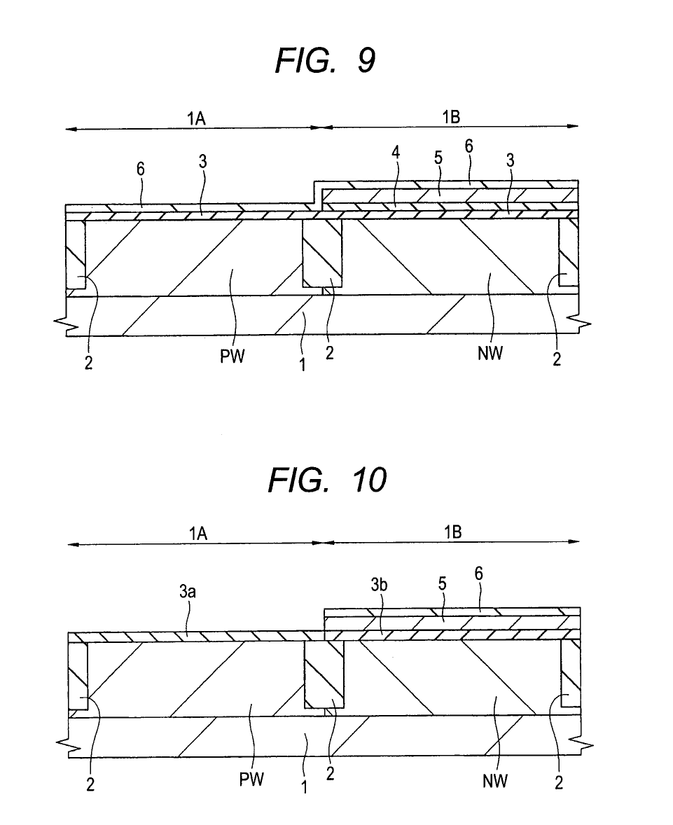

As illustrated in FIG. 9, a rare-earth-containing film (a rare-earth-containing layer) 6 is then formed over the main surface of the semiconductor substrate 1 (Step S11 of FIG. 2).

Since the metal nitride film 5 and the Al-containing film 4 are removed from the nMIS formation region 1A and at the same time, the metal nitride film 5 and the Al-containing film 4 are left in the pMIS formation region 1B by etching in Step S8 and Step S9, the rare-earth-containing film 6 is formed over the Hf-containing insulating film 3 in the nMIS formation region 1A and over the metal nitride film 5 in the pMIS formation region 1B in Step S11. Therefore, the rare-earth-containing film 6 and the Hf-containing insulating film 3 are in contact with each other in the nMIS formation region 1A, while the rare-earth-containing film 6 and the Al-containing film 4 (and the Hf-containing insulating film 3) are not in contact with each other in the pMIS formation region 1B because they have the metal nitride film 5 therebetween.

The rare-earth-containing film 6 contains a rare earth element, particularly preferably La (lanthanum). It also contains Si (silicon), which is one of the characteristics of the film. In short, the rare-earth-containing film 6 is a film containing both a rare earth element (particularly preferably La) and Si (silicon) and is made of a material containing a rare earth element (particularly preferably La) and Si. As the rare-earth-containing film 6, a rare earth silicate film (LnSiO film) is preferred. The rare earth contained in the rare-earth-containing film 6 is particularly preferably La so that the rare-earth-containing film 6 is particularly preferably a lanthanum silicate film (LaSiO film). The rare earth silicate film (LnSiO film) is a material film comprised of a rare earth (Ln), silicon (Si), and oxygen (O) and the lanthanum silicate film (LaSiO film) is a material film comprised of lanthanum (La), silicon (Si), and oxygen (O). The thickness of the rare-earth-containing film 6 can be set at, for example, from about 0.5 nm to 1 nm.

The term “rare earth” or “rare earth element” as used herein means any of lanthanoid series elements from lanthanum (La) to ruthenium (Lu), scandium (Sc), and yttrium (Y). The rare earth element contained in the rare-earth-containing film 6 is called as “Ln”. The gate insulating film containing Hf is called “Hf-based gate insulating film”.

The rare-earth-containing film 6 is formed preferably by sputtering, because the film formed by CVD is likely to contain an impurity such as carbon (C) or chlorine (Cl) but the film formed by sputtering does not easily contain an impurity. In addition, the rare-earth-containing film 6 is thin and such a thin film can be formed by sputtering with good controllability.

When a lanthanum silicate (LaSiO film) is used as the rare-earth-containing film 6 and this lanthanum silicate film (LaSiO film) is formed by sputtering, there are three targets to be used for sputtering.

Firstly, a silicon target (Si target) and a lanthanum oxide target (LaOₓ target) are used for sputtering to form a lanthanum silicate film (LaSiO film). In this case, formation of a lanthanum silicate film (LaSiO film) by sputtering at room temperature (the semiconductor substrate 1 is set at room temperature) enables to effectively diffuse LaOₓ to the substrate side without causing aggregation of Si and LaOₓ. In addition, when a lanthanum silicate film (LaSiO film) is formed over the metal nitride film 5 in the pMIS formation region 1B, the metal nitride film 5 is not oxidized so much. This facilitates removal of the metal nitride film 5 in a removal step of the metal nitride film 5 which will be described later.

Secondly, a silicon oxide target (S10, target) and a lanthanum oxide target (LaO, target) are used for sputtering to form a lanthanum silicate film (LaSiO film). In this case, using a silicon oxide target (SiO_{X} target) enables to compensate for oxygen defects of a high-k gate insulating film, thereby improving the TDDB (time dependence on dielectric breakdown) lifetime or the like.

Thirdly, a lanthanum silicate target (LaSiO target) is used for sputtering to form a lanthanum silicate film (LaSiO film). In this case, using a lanthanum silicate target (LaSiO target) enables to compensate for oxygen defects of a high-k gate insulating film, thereby improving the TDDB (time dependence on dielectric breakdown) lifetime or the like. In addition, although there is a fear of deliquescence occurring due to use of a lanthanum oxide target (LaO, target), it is suppressed when a lanthanum silicate target (LaSiO target) is used. This enables to form a lanthanum silicate film with more stability.

After formation of the rare-earth-containing film 6 in the above-described manner, the resulting semiconductor substrate 1 is heat treated (Step S12 of FIG. 2). In the heat treatment in Step S12, heat treatment can be carried out within a heat treatment temperature range of preferably from 600° C. to 1000° C. in an inert gas atmosphere.

In the heat treatment in Step S12, the Hf-containing insulating film 3 is reacted with the rare-earth-containing film 6 in the nMIS formation region 1A and the Hf-containing insulating film 3 is reacted with the Al-containing film 4 in the pMIS formation region 1B. This means that in the heat treatment in Step S12, the rare-earth-containing film 6 is in contact with the Hf-containing insulating film 3 in the nMIS formation region 1A so that they react with each other to introduce (diffuse) the rare earth element Ln (particularly preferably, Ln=La) configuring the rare-earth-containing film 6 and Si into the Hf-containing insulating film 3. In addition, in the heat treatment in Step S12, the Al-containing film 4 and the Hf-containing insulating film 3 are in contact in the pMIS formation region 1B so that they react with each other to introduce (diffuse) Al configuring the Al-containing film 4 into the Hf-containing insulating film 3. It is to be noted that in the pMIS formation region 1B, the rare-earth-containing film 6 and the Al-containing film 4 (and the Hf-containing insulating film 3) have therebetween the metal nitride film 5 and are therefore not in contact with each other so that neither the Al-containing film 4 nor the Hf-containing insulating film 3 react with the rare-earth-containing film 6 and neither the rare earth element Ln (particularly preferably Ln=La) configuring the rare-earth-containing film 6 nor Si is introduced (diffused) into the Hf-containing insulating film 3 in the pMIS formation region 1B.

The heat treatment in Step S12 causes a reaction (mixing) between the rare-earth-containing film 6 and the Hf-containing insulating film 3 in the MIS formation region 1A to form the Hf-containing insulating film 3a as illustrated in FIG. 10. This means that in the nMIS formation region 1A, the rare earth element Ln (particularly preferably Ln=La) of the rare-earth-containing film 6 and Si are introduced into the Hf-containing insulating film 3 to convert the Hf-containing insulating film 3 into the Hf-containing insulating film 3a. The term “rare earth element” contained in the rare-earth-containing film 6 is expressed as Ln. For example, when the rare-earth-containing film 6 is a lanthanum silicate film (LaSiO film), Ln means La, while when the rare-earth-containing film 6 is an yttrium silicate film (YSiO film), Ln means Y.

In addition, the heat treatment in Step S12 causes a reaction (mixing) between the Al-containing film 4 and the Hf-containing insulating film 3 in the pMIS formation region 1B to form the Hf-containing insulating film 3b as illustrated in FIG. 10. This means that in the pMIS formation region 1B, Al of the Al-containing film 4 is introduced into the Hf-containing insulating film 3 to convert the Hf-containing insulating film 3 into the Hf-containing insulating film 3b.

The Hf-containing insulating film 3a is made of an insulating material containing Hf (hafnium), a rare earth element Ln (particularly preferably, Ln=La), Si (silicon), and O (oxygen). The rare earth element Ln contained in the Hf-containing insulating film 3a is the same as the rare earth element Ln contained in the rare-earth-containing film 6. Accordingly, when the Hf-containing insulating film 3 is an HfON film, the Hf-containing insulating film 3a is an HfLnSiON film (an HfLaSiON film when Ln=La). When the Hf-containing insulating film 3 is an HfO film (typically, an HfO₂ film), the Hf-containing insulating film 3a is an HfLnSiO film (an HfLaSiO film when Ln=La).

On the other hand, the Hf-containing insulating film 3b is made of an insulating material containing Hf (hafnium), Al (aluminum), and O (oxygen) but not containing Si (silicon). The Hf-containing insulating film 3b does not contain Si (silicon) because neither the Hf-containing insulating film 3 nor the Al-containing film 4 contains Si (silicon). Accordingly, when the Hf-containing insulating film 3 is an HfON film, the Hf-containing insulating film 3b becomes an HfAlON film and when the Hf-containing insulating film 3 is an HfO film (typically, an HfO₂ film), the Hf-containing insulating film 3b becomes an HfAlO film.

The rare-earth-containing film 6 is, as described above, preferably a rare earth silicate film (particularly preferably, a lanthanum silicate film). In this case, the rare-earth-containing film 6 contains oxygen (O) as well as a rare earth element Ln and silicon (Si) and the Hf-containing insulating film 3 also contains oxygen (O) so that the Hf-containing insulating film 3a contains oxygen (O) irrespective of whether the oxygen (O) of the rare-earth-containing film 6 is introduced into the Hf-containing insulating film 3 in the heat treatment in Step S12. In practice, not only the rare earth element Ln and silicon (Si) of the rare-earth-containing film 6 but also oxygen (O) of the rare-earth-containing film 6 are introduced into the Hf-containing insulating film 3 to form the Hf-containing insulating film 3a.

The Al-containing film 4 is preferably an aluminum oxide film as described above and in this case, the Al-containing film 4 contains oxygen (O) in addition to aluminum (Al). The Hf-containing insulating film 3 also contains oxygen (O) so that irrespective of whether the oxygen (O) of the Al-containing film 4 is introduced into the Hf-containing insulating film 3 by the heat treatment in Step S12, the Hf-containing insulating film 3b contains oxygen (O). In practice, not only the aluminum (Al) of the Al-containing film 4 but also oxygen (O) of the Al-containing film 4 is introduced into the Hf-containing insulating film 3 to form the Hf-containing insulating film 3b. Accordingly, when the Hf-containing insulating film 3 is an HfON film and the Al-containing film 4 is an aluminum oxide film or an aluminum film, the Hf-containing insulating film 3b is an HfAlON film. When the Hf-containing insulating film 3 is an HfO film (typically, an HfO₂ film) and the Al-containing film 4 is an aluminum oxide film or an aluminum film, the Hf-containing insulating film 3b is an HfAlO film.

When the Al-containing film 4 is an aluminum oxynitride film (AlON film), not only aluminum (Al) of the Al-containing film 4 but also oxygen (O) and nitrogen (N) of the Al-containing film 4 are introduced into the Hf-containing insulating film 3 to convert it into the Hf-containing insulating film 3b. Irrespective of whether the Hf-containing insulating film 3 is an HfON film or an HfO film, the Hf-containing insulating film 3b may be an HfAlON film.

Since the rare-earth-containing film 6 is formed over the metal nitride film 5 in the pMIS formation region 1B, the rare-earth-containing film 6 in the pMIS formation region 1B remains almost unreacted with the metal nitride film 5. This means that a material which is stable even at the heat treatment temperature in the heat treatment in Step S12 and therefore does not easily react with any one of the Hf-containing insulating film 3, the Al-containing film 4, and the rare-earth-containing film 6 is selected in advance as the material of the metal nitride film 5. As such a material, a metal nitride is suited, with titanium nitride (TiN), hafnium nitride (HfN) and zirconium nitride (ZrN) being particularly preferred.

When prior to the formation of the Hf-containing insulating film 3 in Step S4, a thin silicon oxide film (not illustrated) is formed as an interface layer over the surface (silicon surface) of the semiconductor substrate 1 (the p-type well PW and the n-type well NW) and the Hf-containing insulating film 3 is formed over the resulting silicon oxide film as described above, it is preferred to suppress a reaction between the Hf-containing insulating film 3 and the underlying silicon oxide film during the heat treatment in Step S12 and leave the silicon oxide film as an interface layer. In other words, it is preferred to leave a silicon oxide film as an interface layer between the Hf-containing insulating film 3a and the semiconductor substrate 1 (p-type well PW) in the nMIS formation region 1A and to leave a silicon oxide film as an interface layer between the Hf-containing insulating film 3b and the semiconductor substrate 1 (n-type well NW) in the pMIS formation region 1B. This enables to manufacture a good device while suppressing deterioration in driving power or reliability. A silicon oxynitride film may be used instead of the silicon oxide film as the interface layer.

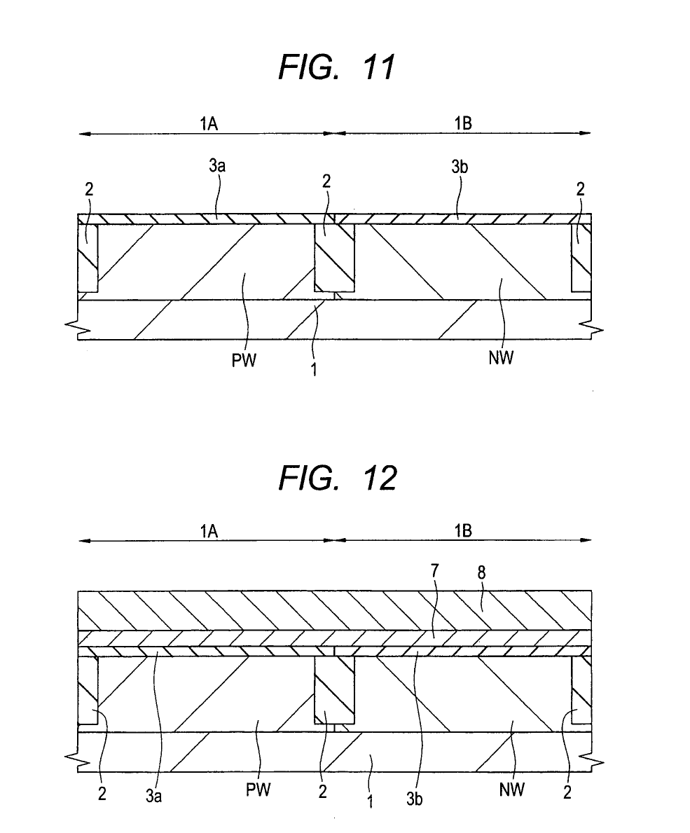

Then, as illustrated in FIG. 11, the rare-earth-containing film 6 which has remained unreacted in the heat treatment in Step S12 (an unreacted portion of the rare-earth-containing film 6) is removed by etching (preferably, wet etching) (Step S13 of FIG. 2). The metal nitride film 5 is then removed by etching (preferably, wet etching) (Step S14 of FIG. 2).

By the etching of the rare-earth-containing film 6 in Step S13, the rare-earth-containing film 6 over the metal nitride film 5 in the pMIS formation region 1B is removed to expose the metal nitride film 5, while the rare-earth-containing film 6 that has remained unreacted with the Hf-containing insulating film 3 in the heat treatment in Step S12 is removed to expose the Hf-containing insulating film 3a in the nMIS formation region 1A. Although the full thickness portion of the rare-earth-containing film 6 in the nMIS formation region 1A sometimes reacts with the Hf-containing insulating film 3 at the time of heat treatment in Step S12, depending on the thickness of the rare-earth-containing film 6 upon formation. Also in this case, the metal nitride film 5 in the pMIS formation region 1B is exposed after the etching of the rare-earth-containing film 6 in Step S13 and the Hf-containing insulating film 3a is exposed in the nMIS formation region 1A. In the etching of the metal nitride film 5 in Step S14, the metal nitride film 5 formed in the pMIS formation region 1B is removed and the Hf-containing insulating film 3b is exposed in the pMIS formation region 1B.

The metal nitride film 5 is a film that does not react readily with the rare-earth-containing film 6 in the heat treatment step of Step S12. Even if the surface layer portion (a portion contiguous to the rare-earth-containing film 6) of the metal nitride film 5 reacts with the rare-earth-containing film 6 by the heat treatment in Step S12 to form a thin TiLnSiON layer (in the case where the metal nitride film 5 is a titanium nitride film) over the surface of the metal nitride film 5, it can be removed by the etching in Step S13 or S14. For the removal of the TiLnSiON layer, it is also possible to carry out etching (preferably wet etching) after the etching of the rare-earth-containing film 6 in Step S13 but prior to the etching of the metal nitride film 5 in Step S14. When the metal nitride film 5 is a metal nitride film other than titanium nitride, the TiLnSiON layer becomes a layer having, instead of Ti, a metal element configuring the metal nitride film 5.

After the etching of the metal nitride film 5 in Step S14, both the Hf-containing insulating film 3a in the nMIS formation region 1A and the Hf-containing insulating film 3b in the pMIS formation region 1B are exposed.

Depending on the thickness of the Al-containing film 4 upon formation of it, the full thickness portion of the Al-containing film 4 in the pMIS formation region 1B may react (mix) with the Hf-containing insulating film 3 to be the Hf-containing insulating film 3b or only the lower layer portion of the Al-containing film 4 in the pMIS formation region 1B may react (mix) with the Hf-containing insulating film 3 to be the Hf-containing insulating film 3b by the heat treatment in Step S12. When the full thickness portion of the Al-containing film 4 in the pMIS formation region 1B reacts (mixes) with the Hf-containing insulating film 3 to form the Hf-containing insulating film 3b by the heat treatment in Step S12, an unreacted portion of the Al-containing film 4 does not remain over the Hf-containing insulating film 3b so that a metal film 7 is formed directly on the Hf-containing insulating film 3b in Step S15 which will be conducted later and the metal film 7 is contiguous to the Hf-containing insulating film 3b. On the other hand, when only the lower layer portion of the Al-containing film 4 in the pMIS formation region 1B reacts (mixes) with the Hf-containing insulating film 3 to form the Hf-containing insulating film 3b by the heat treatment in Step S12, an unreacted portion of the Al-containing film 4 remains as a thin film over the Hf-containing insulating film 3b. An unreacted portion of the Al-containing film 4 therefore exists between the metal film 7 to be formed later in Step S15 and the Hf-containing insulating film 3b. In the p-channel MISFET having an Hf-based gate insulating film and a metal gate electrode, the threshold value of the p-channel MISFET can be reduced when Al is introduced (mixed) in the Hf-based gate insulating film. Even if an Al oxide (Al-containing film 4) is present between the Hf-based gate insulating film and the metal gate electrode, the Al oxide (Al-containing film 4) contributes to a reduction in the threshold value of the p-channel MISFET. It is therefore possible to reduce the threshold value of the p-channel MISFET Qp whether the unreacted portion of the Al-containing film 4 does not remain over the Hf-containing insulating film 3b in the pMIS formation region 1B or the unreacted portion of the Al-containing film 4 remains over the Hf-containing insulating film 3b in the pMIS formation region 1B at the time of heat treatment in Step S12. This means that the present embodiment and also Embodiments 2 and 3 which will be described later are effective in either case where the unreacted portion of the Al-containing film 4 does not remain (exist) between the metal film 7 of the gate electrode GE2 and the Hf-containing insulating film 3b or where it remains (exists) and the threshold value of the p-channel MISFET Qp can be reduced in either case.

In the n-channel MISFET having the Hf-based gate insulating film and the metal gate electrode, on the other hand, the threshold value of the n-channel MISFET can be reduced if a rare earth element such as La is introduced (mixed) in the Hf-based gate insulating film. Even if an La oxide layer has remained unreacted between the Hf-based gate insulating film and the metal gate, this La oxide layer does not contribute to reduction of the threshold value of the n-channel MISFET so much. Introduction of a rare earth element such as La into the Hf-based gate insulating film is effective for reducing the threshold value of the n-channel MISFET. In the present embodiment, the threshold value of the n-channel MISFET Qn can be reduced by carrying out heat treatment in Step S12 to cause reaction (mixing) between the rare-earth-containing film 6 in the nMIS formation region 1A with the Hf-containing insulating film 3 to form an Hf-based gate insulating film (that is, the Hf-containing insulating film 3a) having a rare earth element Ln introduced therein. Even if an unreacted portion of the rare-earth-containing film 6 remains over the Hf-containing insulating film 3a in the nMIS formation region 1A at the time of heat treatment in Step S12, this unreacted portion will be removed by the etching of the rare-earth-containing film 6 in Step S13 so that the metal film 7 will be formed directly on the Hf-containing insulating film 3a in Step S15 which will be described later and the metal film 7 of the gate electrode GE1 is brought into contact with the Hf-containing insulating film 3a.

As illustrated in FIG. 12, the metal film (metal layer, metal gate film) 7 for a metal gate (metal gate electrode) is formed over the main surface of the semiconductor substrate 1 (Step S15 of FIG. 2). In Step S15, the metal film 7 is formed on the Hf-containing insulating film 3a in the nMIS formation region 1A, while the metal film 7 is formed on the Hf-containing insulating film 3b in the pMIS formation region 1B. The metal film 7 is preferably a titanium nitride (TiN) film, a tantalum nitride (TaN) film, or a tantalum carbide (TaC) film, with a titanium nitride (TiN) film being most preferred. The metal film 7 can be formed, for example, by sputtering. The thickness of the metal film 7 can be set at, for example, from about 10 nm to 20 nm.

The term “metal film (metal layer)” as used herein means an electroconductive film (electroconductive layer) showing metal conductivity and it embraces not only a simple metal film or alloy film but also a metal compound film (such as metal nitride film or metal carbide film) showing metal conductivity. The metal film 7 is therefore an electroconductive film showing metal conductivity and having a resistivity as low as that of a metal. It is preferably a titanium nitride (TiN) film, a tantalum nitride (TaN) film, or a tantalum carbide (TaC) film.

A silicon film 8 is then formed over the main surface of the semiconductor substrate 1, that is, over the metal film 7 (Step S16 of FIG. 2). The silicon film 8 may be either a polycrystalline silicon film or an amorphous silicon film. Even when it is an amorphous silicon film at the time of film formation, it becomes a polycrystalline silicon film by the heat treatment after film formation (for example, by the activation annealing of an impurity introduced for source/drain). The thickness of the silicon film 8 can be set at, for example, about 100 nm.

Although the formation of the silicon film 8 in Step S16 can be omitted by increasing the thickness of the metal film 7 to be formed in Step S15 (this means that the gate electrodes GE1 and GE2 are formed using the metal film 7 without using the silicon film 8), it is preferred to form the silicon film 8 over the metal film 7 in Step S16 (this means that gate electrodes GE1 and GE2 are formed of a film stack of the metal film 7 and the overlying silicon film 8). The reason is that the metal film 7 having an excessively large thickness has problems such as easy separation of the metal film 7 and possibility of the substrate being damaged by overetching upon pattering of the metal film 7. In the gate electrode formed of a film stack of the metal film 7 and the silicon film 8, compared with the gate electrode formed only of the metal film 7, the thickness of the metal film 7 can be reduced, making it possible to overcome the above-described problems. In addition, formation of the silicon film 8 over the metal film 7 is also advantageous from the standpoints of minute processing, manufacturing cost, and yield, because it can follow the conventional processing method or process of a polysilicon gate electrode (gate electrode made of polysilicon).

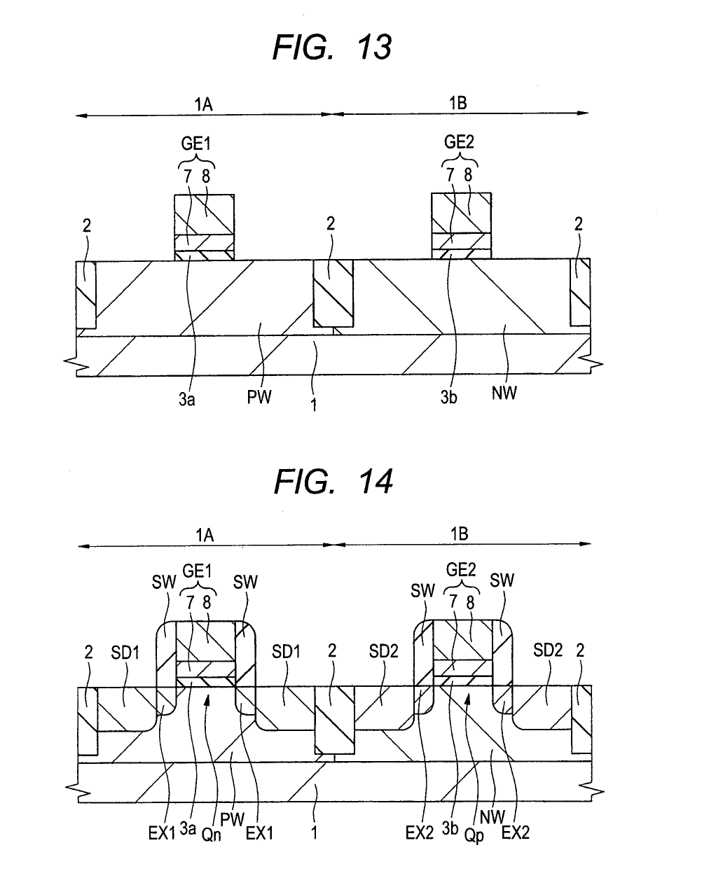

As illustrated in FIG. 13, the film stack of the silicon film 8 and the metal film 7 is then patterned by using photolithography and etching (preferably, dry etching) to form the gate electrodes GE1 and GE2 made of the metal film 7 and the silicon film 8 over the metal film 7 (Step 17 of FIG. 2).

The gate electrode GE1 is formed over the Hf-containing insulating film 3a in the nMIS formation region 1A and the gate electrode GE2 if formed over the Hf-containing insulating film 3b in the pMIS formation region 1B. In other words, the gate electrode GE1 made of the metal film 7 and the silicon film 8 over the metal film 7 is formed over the surface of the p-type well PW in the nMIS formation region 1A via the Hf-containing insulating film 3a serving as a gate insulating film, while the gate electrode GE2 made of the metal film 7 and the silicon film 8 over the metal film 7 is formed over the surface of the n-type well NW in the pMIS formation region 1B via the Hf-containing insulating film 3b serving as a gate insulating film. The Hf-containing insulating film 3a and the Hf-containing insulating film 3b each have a permittivity (dielectric constant) higher than that of silicon oxide.

After dry etching for patterning the silicon film 8 and the metal film 7 in Step S17, it is preferred to carry out wet etching for removing a portion of the Hf-containing insulating film 3a not covered with the gate electrode GE1 and a portion of the Hf-containing insulating film 3b not covered with the gate electrode GE2. The Hf-containing insulating film 3a located below the gate electrode GE1 and the Hf-containing insulating film 3b located below the gate electrode GE2 remain without being removed by dry etching in Step S17 and subsequent wet etching. On the other hand, a portion of the Hf-containing insulating film 3a not covered with the gate electrode GE1 and the Hf-containing insulating film 3b not covered with the gate electrode GE2 are removed by dry etching for patterning of the silicon film 8 and the metal film 7 in Step S17 and subsequent wet etching.

As illustrated in FIG. 14, n⁻ type semiconductor regions EX1 are formed by implanting an n type impurity such as phosphorus (P) or arsenic (As) into regions of the p-type well PW on both sides of the gate electrode GE1 in the nMIS formation region 1A. Upon ion implantation for forming the n⁻ type semiconductor regions EX1, the pMIS formation region 1B is covered with a photoresist film (not illustrated) serving as an ion-implantation preventing mask and ion implantation is carried out into the semiconductor substrate 1 (p-type well PW) in the nMIS formation region 1A with the gate electrode GE1 as a mask. On the other hand, p⁻ type semiconductor regions EX2 are formed by implanting a p type impurity such as boron (B) into regions of the n-type well NW on both sides of the gate electrode GE2 in the pMIS formation region 1B. Upon ion implantation for forming the p⁻ type semiconductor regions EX2, the nMIS formation region 1A is covered with another photoresist film (not illustrated) serving as an ion-implantation preventing mask and ion implantation is carried out into the semiconductor substrate 1 (n-type well NW) in the pMIS formation region 1B with the gate electrode GE2 as a mask. The n⁻ type semiconductor regions EX1 may be formed first or alternatively, the p⁻ type semiconductor regions EX2 may be formed first.

Next, sidewalls (sidewall spacers, sidewall insulating films) SW made of an insulator are then formed over the side surfaces of each of the gate electrodes GE1 and GE2. For example, a silicon oxide film and a silicon nitride film are stacked successively in the order of mention over the semiconductor substrate 1 so as to cover the gate electrodes GE1 and GE2 and then anisotropically etching (etching back) the resulting film stack of the silicon oxide film and the silicon nitride film to form the sidewalls SW made of the remaining silicon oxide film and the silicon nitride film over the side surfaces of each of the gate electrodes GE1 and GE2. It is to be noted that to simplify the drawing, the silicon oxide film and the silicon nitride film configuring the sidewall SW are illustrated as one film in FIG. 14.

Next, n⁺ type semiconductor regions SD1 are formed by implanting an n type impurity such as phosphorus (P) or arsenic (As) into regions of the p-type well PW on both sides of the gate electrode GE1 and sidewalls SW in the nMIS formation region 1A. The n⁺ type semiconductor regions SD1 have a higher impurity concentration and a greater junction depth than those of the n⁻ type semiconductor regions EX1. Upon ion implantation for forming these n⁺ type semiconductor region SD1, ion implantation into the semiconductor substrate 1 (p-type well PW) in the nMIS formation region 1A is performed with the gate electrode GE1 and the sidewalls SW over the side surfaces thereof as a mask, while covering the pMIS formation region 1B with a photoresist film (not illustrated) as an ion-implantation preventing mask. Therefore, the n⁻ type semiconductor regions EX1 are formed in alignment with the gate electrode GE1, while the n⁺ type semiconductor regions SD1 are formed in alignment with the sidewalls SW. In addition, p⁺ type semiconductor regions SD2 are formed by implanting a p type impurity such as boron (B) into regions of the n-type well NW on both sides of the gate electrode GE2 and the sidewalls SW in the pMIS formation region 1B. The p⁺ type semiconductor regions SD2 have a higher impurity concentration and a greater junction depth than those of the p⁻ type semiconductor regions EX2. Upon ion implantation for forming these p⁺ type semiconductor region SD2, ion implantation into the semiconductor substrate 1 (n-type well NW) in the pMIS formation region 1B is performed with the gate electrode GE2 and the sidewalls SW over the side surfaces thereof as a mask, while covering the nMIS formation region 1A with another photoresist film (not illustrated) as an ion-implantation preventing mask. Therefore, the p⁻ type semiconductor regions EX2 are formed in alignment with the gate electrode GE2, while the p⁺ type semiconductor regions SD2 are formed in alignment with the sidewalls SW. The n⁺ type semiconductor regions SD1 may be formed first or the p⁺ type semiconductor regions SD2 may be formed first.

By the introduction of an n type impurity in the ion implantation step for forming the n⁻ type semiconductor regions EX1 or the ion implantation step for forming the type semiconductor regions SD1, the silicon film 8 configuring the gate electrode GE1 in the nMIS formation region 1A becomes an n type silicon film. On the other hand, by the introduction of a p type impurity in the ion implantation step for forming the p⁻ type semiconductor regions EX2 or the ion implantation step for forming the p⁺ type semiconductor regions SD2, the silicon film 8 configuring the gate electrode GE2 in the pMIS formation region 1B becomes a p type silicon film.

After ion implantation, annealing (activation annealing, heat treatment) is performed to activate the impurity thus introduced. This enables to activate the impurities introduced into the n⁻ type semiconductor regions EX1, the p⁻ type semiconductor regions EX2, the n⁺ type semiconductor regions SD1, the p⁺ type semiconductor regions SD2, and the silicon film 8.

In such a manner, the structure as illustrated in FIG. 14 can be obtained. The n-channel MISFET Qn is formed as a field effect transistor in the nMIS formation region 1A and the p-channel MISFET Qp is formed as a field effect transistor in the pMIS formation region 1B.

The gate electrode GE1 functions as a gate electrode of the n-channel MISFET Qn and the Hf-containing insulating film 3a below the gate electrode GE1 functions as a gate insulating film of the n-channel MISFET Qn. An n type semiconductor region (impurity diffusion layer) functioning as a source or drain of the n-channel MISFET Qn is formed from the n⁺ type semiconductor region SD1 and the n⁻ type semiconductor region EX1. The gate electrode GE2 functions as a gate electrode of the p-channel MISFET Qp and the Hf-containing insulating film 3b below the gate electrode GE2 functions as a gate insulating film of the p-channel MISFET Qp. A p type semiconductor region (impurity diffusion layer) functioning as a source or drain of the p channel MISFET Qp is formed from the p⁺ type semiconductor region SD2 and the p⁻ type semiconductor region EX2.

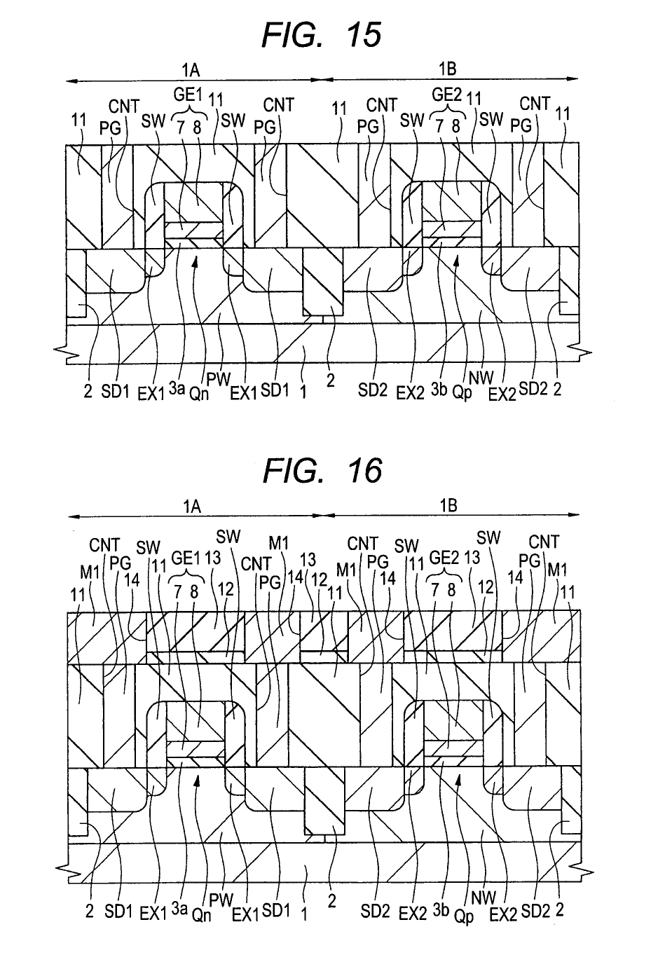

As illustrated in FIG. 15, an insulating film (interlayer insulating film) 11 is then formed over the main surface of the semiconductor substrate 1 so as to cover therewith the gate electrodes GE1 and GE2, and the sidewalls SW. The insulating film 11 is made of, for example, a simple silicon oxide film or a film stack of a thin silicon nitride film and a thick silicon oxide film thereover. After formation of the insulating film 11, the surface of the insulating film 11 is made flat by using, for example, CMP (chemical mechanical polishing).

Then, with a photoresist pattern (not illustrated) formed over the insulating film 11 as an etching mask, the insulating film 11 is dry etched to form a contact hole (throughhole, hole) CNT in the insulating film 11. The contact hole CNT is formed above the n⁺ type semiconductor regions SD1, the p⁺ type semiconductor regions SD2, and the gate electrodes GE1 and GE2.

An electroconductive plug (conductor portion for coupling) made of, for example, tungsten (W) is then formed in the contact hole CNT. The plug PG is formed in the following manner. First, a barrier conductor film (for example, a titanium film, a titanium nitride film, or a film stack of them) is formed over the insulating film 11 including that inside (on the bottom and side surfaces) of the contact hole CNT. Then, a main conductor film comprised of, for example, a tungsten film is formed over the barrier conductor film so as to fill the contact hole CNT, followed by removal of unnecessary portions of the main conductor film and the barrier conductor film over the insulating film 11 by CMP or etch back. To simplify the drawing, the barrier conductor film and the main conductor film (tungsten film) configuring the plug PG is illustrated as one film in FIG. 15.

As illustrated in FIG. 16, a stopper insulating film (etching stopper insulating film) 12 and an interconnect forming insulating film (interlayer insulating film) 13 are formed successively over the insulating film 11 having therein the plug PG. The stopper insulating film 12 is a film to be an etching stopper upon processing of a trench in the insulating film 13 so that it is made of a material having an etch selectivity to the insulating film 13. For example, the stopper insulating film 12 is made of a silicon nitride film and the insulating film 13 is made of a silicon oxide film.

A first-level interconnect M1 is then formed by the single damascene process. First, after formation of an interconnect trench 14 in a predetermined region of the insulating film 13 and the stopper insulating film 12 by dry etching with a resist pattern (not illustrated) as a mask, a barrier conductor film (for example, a titanium nitride film, a tantalum film, or a tantalum nitride film) is formed over the main surface of the semiconductor substrate 1 (over the insulating film 13 including that on the bottom and side surfaces of the interconnect trench 14). Then, a copper seed layer is formed over the barrier conductor film by CVD or sputtering. A copper plating film is then formed over the seed layer by using electroplating or the like and the interconnect trench 14 is filled with the resulting copper plating film. Then, the copper plating film, the seed layer, and the barrier metal film in a region outside the interconnect trench 14 are removed by CMP to form a first-level interconnect M1 using, as the main electroconductive material thereof, copper. To simplify the drawing, the copper plating film, the seed layer, and the barrier conductor film configuring the interconnect M1 are illustrated as one film in FIG. 16.

The interconnect M1 is electrically coupled, via the plug PG, to the n⁺ type semiconductor regions SD1 and the p⁺ type semiconductor regions SD2 for forming the source and drain of the n-channel MISFET Qn and the p-channel MISFET Qp. Second- and higher-level interconnects are then formed by the dual damascene process, but they are not illustrated here and description on them is also omitted. The interconnect M1 and higher-level interconnects are not limited to a damascene interconnect and they can be formed by patterning an interconnect conductor film. They may be, for example, a tungsten interconnect or aluminum interconnect.

The characteristics of the present embodiment will next be described in detail.

In the present embodiment, the gate electrodes GE1 and GE2 in the n-channel MISFET Qn and the p-channel MISFET Qp have, on the gate insulating films (corresponding to the Hf-containing insulating films 3a and 3b) thereof, the metal film 7. They are therefore so-called metal gate electrodes. Such a structure enables to downsize an MISFET device (thinning of the gate insulating film) because it can suppress a depletion phenomenon of the gate electrode and minimize parasitic capacitance.

In addition, in the present embodiment, the Hf-containing insulating film 3a having a high permittivity than silicon oxide is used as the gate insulating film of the n-channel MISFET Qn and the Hf-containing insulating film 3b having a higher permittivity than silicon oxide is used as the gate insulating film of the p-channel MISFET Qp. This means that the Hf-containing insulating film 3a and the Hf-containing insulating film 3b which are material films having a higher permittivity (dielectric constant) than silicon oxide, so-called high-k films (high dielectric constant films), are used as the gate insulating films in the n-channel MISFET Qn and the p-channel MISFET Qp. It is therefore possible to increase the physical thickness of the Hf-containing insulating film 3a and the Hf-containing insulating film 3b, thereby decreasing a leakage current, compared with the case where a silicon oxide film is used as the gate insulating films of the n-channel MISFET Qn and the p-channel MISFET Qp.

Furthermore, in the present embodiment, it is possible to reduce the absolute value of the threshold value (threshold voltage) of the n-channel MISFET Qn by using, as the gate insulating film of the n-channel MISFET Qn, the Hf-containing insulating film 3a, which is a High-k film having a rare earth element Ln (particularly preferably Ln=La) introduced therein. In short, the threshold value of the n-channel MISFET Qn can be reduced. In addition, by using the Hf-containing insulating film 3b, which is a High-k film having Al introduced therein, as the gate insulating film of the p-channel MISFET Qp, the absolute value of the threshold value (threshold voltage) of the p-channel MISFET Qp can be reduced. In short, the threshold value of the p-channel MISFET Qp can be reduced. This makes it possible to reduce the threshold value of each of the n-channel MISFET Qn and the p-channel MISFET Qp.

For reducing the threshold voltage of both the n-channel MISFET and the p-channel MISFET, it is preferred that not only the Hf-based gate insulating film of the n-channel MISFET contains a rare earth element and the Hf-based gate insulating film of the p-channel MISFET contains Al but also the Hf-based gate insulating film of the n-channel MISFET does not contain Al and the Hf-based gate insulating film of the p-channel MISFET does not contain a rare earth element (particularly, La). It is therefore preferred that the Hf-containing insulating film 3a, which is the gate insulating film of the n-channel MISFET Qn, does not contain Al and at the same time the Hf-containing insulating film 3b, which is the gate insulating film of the p-channel MISFET Qp does not contain a rare earth element (particularly, La).

In the present embodiment, an insulating film (preferably, an HfON film or an HfO film) containing Hf but containing neither a rare earth element (particularly, La) nor Al is formed as the Hf-containing insulating film 3 and this Hf-containing insulating film 3 is reacted with the rare-earth-containing film 6 to form the Hf-containing insulating film 3a and this Hf-containing insulating film 3 is reacted with the Al-containing film 4 to form the Hf-containing insulating film 3b. This enables to form the Hf-containing insulating film 3a as an insulating film (Hf-based gate insulating film) containing both Hf and a rare earth element Ln but not containing Al and the Hf-containing insulating film 3b as an insulating film (Hf-based gate insulating film) containing both Hf and Al but not containing a rare earth element Ln. As a result, it is possible to efficiently reduce the threshold value of each of the re-channel MISFET Qn and the p-channel MISFET Qp.

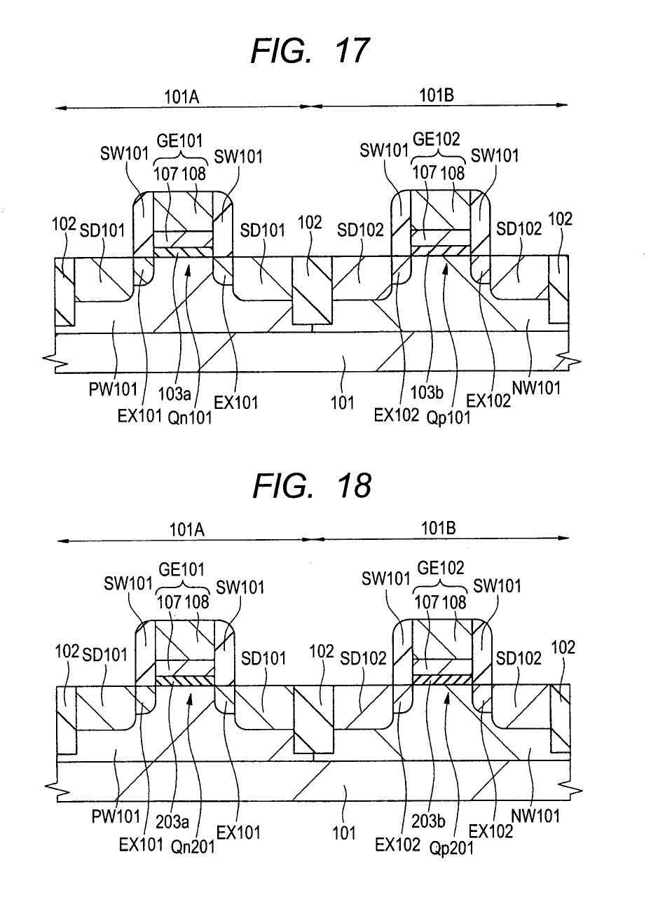

Furthermore, one of the main characteristics of the present embodiment resides in that Si is introduced into the Hf-based gate insulating film (corresponding to the Hf-containing insulating film 3a) of the n-channel MISFET Qn while Si is not introduced into the Hf-based gate insulating film (corresponding to the Hf-containing insulating film 3b) of the p-channel MISFET Qp. This characteristic will next be described compared with comparative examples shown in FIGS. 17 and 18.

FIG. 17 is a fragmentary cross-sectional view of a semiconductor device of a first comparative example investigated by the present inventors and FIG. 18 is a fragmentary cross-sectional view of a semiconductor device of a second comparative example investigated by the present inventors. They correspond to FIG. 1.

The semiconductor device of the first comparative example illustrated in FIG. 17 has an n-channel MISFET Qn 101 formed in an nMIS formation region 101A of a semiconductor substrate 101 and a p-channel MISFET Qp 101 formed in a pMIS formation region 101B of the semiconductor substrate 101.

In the nMIS formation region 101A and the pMIS formation region 101B of the semiconductor substrate 101 defined by an element isolation region 102, a p-type well PW101 and an n-type well NW101 are formed, respectively. Over the surface of the p-type well PW101 in the nMIS formation region 101A, a gate electrode GE101 of the n-channel MISFET Qn 101 is formed via an HfLaSiON film 103a functioning as a gate insulating film. Over the surface of the n-type well NW101 in the pMIS formation region 101B, a gate electrode GE102 of a p-channel MISFET Qp 101 is formed via an HfAlSiON film 103b functioning as a gate insulating film. Each of the gate electrodes GE101 and GE102 is made of a film stack of a metal film 107 and a silicon film 108 over the metal film 107. The HfLaSiON film 103a and the HfAlSiON film 103b are each a so-called High-k film and the gate electrodes GE101 and GE102 are metal gate electrodes. The HfLaSiON film 103a containing La is used as the gate insulating film of the n-channel MISFET Qn 101 and the HfAlSiON film 103b containing Al is used as the gate insulating film of the p-channel MISFET Qp 101 in order to reduce the threshold value of both the MISFET Qn 101 and the p-channel MISFET Qp 101.

In the p-type well PW101 in the nMIS formation region 101A, n⁻ type semiconductor regions EX101 and n⁺ type semiconductor regions SD101 having a higher impurity concentration than the former ones are formed as source/drain regions of the n-channel MISFET Qn 101 having an LDD structure. In the n-type well NW101 in the pMIS formation region 101B, on the other hand, p⁻ type semiconductor regions EX102 and p⁺ type semiconductor regions SD102 having a higher impurity concentration than the former ones are formed as source/drain regions of the p-channel MISFET Qp 101 having an LDD structure. The gate electrodes GE101 and GE102 have, over the side surfaces thereof, sidewalls SW101 each made of an insulator.

Also in the semiconductor device of the first comparative example illustrated in FIG. 17, members corresponding to the insulating film 11, the contact hole CNT, the plug PG, the stopper insulating film 12, the insulating film 13, the interconnect trench 14, and the interconnect M1 of the present embodiment are formed. To simplify the drawing, however, they are not illustrated therein and description on them is also omitted.

The semiconductor device of the first comparative Example having such a structure and illustrated in FIG. 17 can be obtained by forming an HfSiON film common to both the nMIS formation region 101A and the pMIS formation region 101B, selectively introducing La into the HfSiON film in the nMIS formation region 101A to form an HfLaSiON film 103a, and selectively introducing Al into the HfSiON film in the pMIS formation region 101B to form an HfAlSiON film 103b.

The investigation by the present inventors has however revealed that the following problem occurs in the semiconductor device of the first comparative example illustrated in FIG. 17.

Aluminum oxide has a dielectric constant much smaller than that of a rare earth oxide. For example, La oxide has a dielectric constant of about 38, while, Al oxide has a dielectric constant of about 10. When, as the semiconductor device of the first comparative example illustrated in FIG. 17, La is selectively introduced into the common HfSiON film to form the HfLaSiON film 103a and Al is selectively introduced to form the HfAlSiON film 103b, the dielectric constant of the HfAlSiON film 103b, which is a gate insulating film of the p-channel MISFET Qp 101, becomes much lower than that of the HfLaSiON film 103a which is a gate insulating film of the n-channel MISFET Qn 101. As a result, the EOT (equivalent oxide thickness) of the gate insulating film (HfAlSiON film 103b) of the p-channel MISFET Qp 101 becomes much greater than that of the gate insulating film (HfLaSiON film 103a) of the n-channel MISFET Qn 101, leading to a large difference in EOT of the gate insulating film between the n-channel MISFET Qn 101 and the p-channel MISFET Qp 101. Accordingly, even if the EOT of the gate insulating film (HfLaSiON film 103a) of the n-channel MISFET Qn 101 is small, a large EOT of the gate insulating film (HfAlSiON film 103b) of the p-channel MISFET Qp 101 causes deterioration in the characteristics of CMISFET. To improve the performance of a semiconductor device, a further reduction in EOT is desired.

Using an Hf-based gate insulating film not containing Si is effective for reducing the EOT of a gate insulating film. For example, HfSiON has a dielectric constant of about 20, while HfON has a dielectric constant of about 40, twice as much as that of HfSiON. It is therefore considered to use, as in the semiconductor device of the second comparative example illustrated in FIG. 18, an Hf-based gate insulating film not containing Si as the gate insulating film of both of an re-channel MISFET Qn 201 and a p-channel MISFET Qp 201.

The semiconductor device of the second comparative example illustrated in FIG. 18 has a similar configuration to that of the semiconductor device of the first comparative example illustrated in FIG. 17 except that it uses, as the gate insulating film of the n-channel MISFET Qn 201, an HfLaON film 203a instead of the HfLaSiON film 103a and, as the gate insulating film of the p-channel MISFET Qp 201, an HfAlON film 203b instead of the HfAlSiON film 103b. The semiconductor device of the second comparative example having such a structure and illustrated in FIG. 18 can be obtained by forming an HfON film common to both the nMIS formation region 101A and the pMIS formation region 101B, selectively introducing La into the HfON film in the nMIS formation region 101A to form the HfLaON film 203a and selectively introducing Al into the HfON film in the pMIS formation region 101B to form the HfAlON film 203b.

When the HfLaON film 203a and the HfAlON film 203b are used as the gate insulating films of the n-channel MISFET Qn 201 and the p-channel MISFET Qp 201, respectively, the dielectric constant of the gate insulating films can be made greater than that of the semiconductor device of the first comparative example illustrated in FIG. 17 in which the HfLaSiON film 103a and the HfAlSiON film 103b are used as the gate insulating films. This is because the dielectric constant of the HfLaON film 203a is greater than that of the HfLaSiON film 103a and the dielectric constant of the HfAlON film 203b is greater than that of the HfAlSiON film 103b. In the semiconductor device of the second comparative example illustrated in FIG. 18, compared with the semiconductor device of the first comparative example illustrated in FIG. 17, the EOT of the gate insulating film of both the n-channel MISFET Qn 201 and the p-channel MISFET Qp 201 can be reduced.

The investigation by the present inventors has however revealed that the following problem occurs in the semiconductor device of the second comparative example illustrated in FIG. 18.

In the HfLaSiON film, a binding power between La and Hf is weaker than that between La and Si. The HfLaON film 203a containing no Si does not have an La—Si bond having a high binding power so that a binding power of La is weaker than that in the HfLaSiON film 103a containing Si. At the time of dry etching for processing the gate electrodes GE101 and GE102 (more specifically, patterning of a film stack of a metal film 107 and a silicon film 108 thereover) or wet etching of a portion of the HfLaON film 203a and the HfAlON film 203 not covered with the gate electrodes GE101 and GE102, LaO easily dissociates or is eluted from the HfLaON film 203a. There is a risk of inconveniences such as generation of foreign matters and retreat of the HfLaON film 203a, which is a gate insulating film, from the side surfaces of the gate electrodes GE101 and GE102. These inconveniences may deteriorate the performance of a semiconductor device. On the other hand, the HfAlON film 203b does not cause such problems of the HfLaON film 203a or even if they occur, they are slight compared with those of the HfLaON film 203a. Such an advantage is presumed to owe to a stronger binding power between Al and Hf in the HfAlON film 203b than that between La and Hf in the HfLaON film 203a.

In the semiconductor device of the second comparative example illustrated in FIG. 18, formation of the HfON film common to the nMIS formation region 101A and the pMIS formation region 101B is followed by selective introduction of La into the HfON film in the nMIS formation region 101A to form the HfLaON film 203a. Described specifically, the HfLaON film 203a is formed by forming an La oxide film over the HfON film in the nMIS formation region 101A and then reacting (mixing) the La oxide film with the HfON film by heat treatment. In the semiconductor device of the first comparative example illustrated in FIG. 17, on the other hand, the HfLaSiON film 103a is formed by forming the HfSiON film common to the nMIS formation region 101A and the pMIS formation region 101B, forming an La oxide film over the HfSiON film in the nMIS formation region 101A, and reacting (mixing) the La oxide film with the HfSiON film by heat treatment.

When the La oxide film is reacted (mixed) with the HfON film or HfSiON film by heat treatment, La oxide is diffused in the HfON film or HfSiON film in a substrate direction (direction approaching the semiconductor substrate 101) to form the HfLaSiON film 103a or the HfLaON film 203a. This enables to reduce the work function of the gate electrode GE101, thereby reducing the threshold value of the n-channel MISFET Qn 101 or Qp 201.

The investigation by the present inventors has revealed that in the HfLaON film 203a formed by reacting (mixing) the HfON film with the La oxide film by heat treatment, compared with in the HfLaSiON film 103a formed by reacting (mixing) the HfSiON film and the La oxide film by heat treatment, a binding power between La and Hf is weaker than that between La and Si so that the La oxide cannot be diffused readily in the substrate direction. For reducing the threshold value by introducing La into the Hf-based gate insulating film of the n-channel MISFET, the threshold value (absolute value of it) is likely to decrease more when La is diffused sufficiently in the Hf-based gate insulating film in the substrate direction. In the n-channel MISFET Qn 201 of the second comparative example using the HfLaON film 203a as a gate insulating film compared with the n-channel MISFET Qn 101 of the first comparative example using the HfLaSiON film 103a as a gate insulating film, an effect of reducing the work function of the gate electrode GE101 produced by the introduction of La into the Hf-based gate insulating film decreases, leading to a decrease in the effect of reducing the threshold value. In other words, when the introduction amounts of La into the Hf-based gate insulating films (HfLaSiON film 103a and HfLaON film 203a) are the same, the absolute value of the threshold voltage becomes greater in the n-channel MISFET Qn 201 of the semiconductor device of the second comparative example using the HfLaON film 203a as a gate insulating film compared with the n-channel MISFET Qn 101 of the semiconductor device of the first comparative example using the HfLaSiON film 103a as a gate insulating film. On the other hand, the HfAlON film 203b does not cause such a problem as that of the HfLaON film 203a. Even if the problem occurs, it is more minor than that of the HfLaON film 203a.

When La is introduced into the Hf-based gate insulating film of the n-channel MISFET, the problem described in relation to the first and second comparative examples illustrated in FIGS. 17 and 18 is particularly marked. It however occurs when a rare earth element other than La is used. It also occurs when the HfLaSiON film 103a, the HfAlSiON film 103b, the HfLaON film 203a, and the HfAlON film 203b are an HfLaSiO film (103a), an HfAlSiO film (103b), an HfLaO film (203a), and an HfAlO film (203b), respectively.

In the present embodiment, Si is introduced into the Hf-based gate insulating film (corresponding to the Hf-containing insulating film 3a) of the n-channel MISFET Qn, but Si is not introduced into the Hf-based gate insulating film (corresponding to the Hf-containing insulating film 3b) of the p-channel MISFET Qp. This means that in the present embodiment, the Hf-containing insulating film 3a, which is a gate insulating film of the n-channel MISFET Qn, contains Hf, Ln, Si, and O, while the Hf-containing insulating film 3b, which is a gate insulating film of the p-channel MISFET Qp, contains Hf, Al, and O but not Si.

In the semiconductor device of the first comparative example illustrated in FIG. 17, a reduction in dielectric constant of the Hf-based gate insulating film of the p-channel MISFET Qp 101 is the problem to overcome. In the present embodiment, the Hf-based gate insulating film (corresponding to the Hf-containing insulating film 3b) of the p-channel MISFET Qp does not contain Si so that it can have a greater dielectric constant than the Hf-based gate insulating film containing Si (first comparative example). On the other hand, the Hf-based gate insulating film (Hf-containing insulating film 3a) of the n-channel MISFET Qn contains not Al but a rare earth element Ln (particularly preferably, La) so that it has a greater dielectric constant. Even if it contains Si, reduction in dielectric constant can therefore be suppressed.

Thus, in the present embodiment, the Hf-based gate insulating film (Hf-containing insulating film 3a) of the n-channel MISFET Qn contains not Al but a rare earth element Ln (particularly preferably, La) so that it can have a greater dielectric constant, while the Hf-based gate insulating film (Hf-containing insulating film 3b) of the p-channel MISFET Qp does not contain Si so that it can have a greater dielectric constant. Accordingly, both the gate insulating film (Hf-containing insulating film 3a) of the n-channel MISFET Qn and the gate insulating film (Hf-containing insulating film 3b) of the p-channel MISFET Qp can have a greater dielectric constant so that a difference in EOT of the gate insulating film between the n-channel MISFET Qn and the p-channel MISFET Qp can be decreased. As a result, the CMISFET equipped with the n-channel MISFET Qn and the p-channel MISFET Qp can have improved characteristics and the semiconductor device can have improved performance.

The semiconductor device of the second comparative example illustrated in FIG. 18 has the above-described problem due to a weak binding power of La (rare earth element) because the Hf-based gate insulating film (HfLaON film 203a) of the n-channel MISFET Qn 201 does not contain Si. In the present embodiment, on the other hand, since the Hf-containing insulating film 3a containing Si is used as the Hf-based gate insulating film of the n-channel MISFET Qn, the problem which has occurred in the second comparative example illustrated in FIG. 18 can be prevented. This means that in the present embodiment, the Hf-containing insulating film 3a, which is a gate insulating film of the n-channel MISFET Qn, contains Hf, Ln, Si, and O so that a rare earth element Ln can bind to Si firmly (can form an Ln—Si bond having a strong binding power), which means enhancement of the binding power of the rare earth element Ln. It is therefore possible to prevent dissociation or elution of LnO from the Hf-containing insulating film 3a at the time of dry etching for processing of the gate electrodes GE1 and GE2 (that is, patterning of the film stack of the metal film 7 and the silicon film 8 thereover) or wet etching of the Hf-containing insulating films 3a and 3b not covered with the gate electrodes GE1 and GE2. This makes it possible to prevent generation of foreign matters and also prevent an undesired retreat of the Hf-containing insulating film 3a, which is a gate insulating film, from the side surfaces of the gate electrodes GE1 and GE2. In addition, in the present embodiment, the Hf-containing insulating film 3a contains not only Hf, Ln, and O but also Si so that an effect of reducing the work function of the gate electrode GE1 produced by introducing a rare earth element (particularly La) into the Hf-based gate insulating film can be enhanced and an effect produced by reducing the threshold voltage of the n-channel MISFET Qn can also be enhanced. This means that the absolute value of the threshold value of the n-channel MISFET Qn can be made smaller than the absolute value of the threshold value of the n-channel MISFET Qn 201 of the semiconductor device of the second comparative example. As a result, the CMISFET equipped with the n-channel MISFET Qn and the p-channel MISFET Qp can have improved characteristics and the semiconductor device can have improved performance.

Furthermore, in the present embodiment, the gate insulating film of the n-channel MISFET Qn and the gate insulating film of the p-channel MISFET Qp are formed separately by forming the Hf-containing insulating film 3, which is common to the nMIS formation region 1A and the pMIS formation region 1B, in both regions, reacting the Hf-containing insulating film 3 in the nMIS formation region 1A with the rare-earth-containing film 6 by heat treatment, and reacting the Hf-containing insulating film 3 of the p-channel MISFET Qp with the Al-containing film 4 by heat treatment. Since the rare-earth-containing film 6 contains not only a rare earth element Ln but also Si and the Al-containing film 4 does not contain Si, Si can be introduced selectively into the gate insulating film (Hf-containing insulating film 3a) of the n-channel MISFET Qn. This makes it possible to individually form the gate insulating film (the Hf-containing insulating film 3a) of the n-channel MISFET Qn containing Hf, a rare earth element Ln, Si, and O as main components thereof and the gate insulating film (Hf-containing insulating film 3b) of the p-channel MISFET Qp containing Hf, Al, and O as main components thereof but not containing Si as a main component thereof while suppressing the number of manufacturing steps. As a result, the semiconductor device can have improved performance while suppressing a manufacturing time or manufacturing cost of it. In addition, the throughput of the semiconductor device can be improved.

Further, in the present embodiment, by carrying out heat treatment in Step S12 while placing the metal nitride film 5 serving as a mask layer (reaction-preventing mask layer) between the Al-containing film 4 and the rare-earth-containing film 6 in the pMIS formation region 1B, the rare-earth-containing film 6 is prevented from reacting with the Al-containing film 4 or the Hf-containing insulating film 3 in the pMIS formation region 1B. It is therefore possible to form the gate insulating film (Hf-containing insulating film 3a) of the n-channel MISFET Qn and the gate insulating film (Hf-containing insulating film 3b) of the p-channel MISFET Qp individually by single heat treatment in Step S12. As a result, it is possible to reduce the number of manufacturing steps of the semiconductor device, thereby reducing the manufacturing time or improving throughput of the semiconductor device.

### Embodiment 2

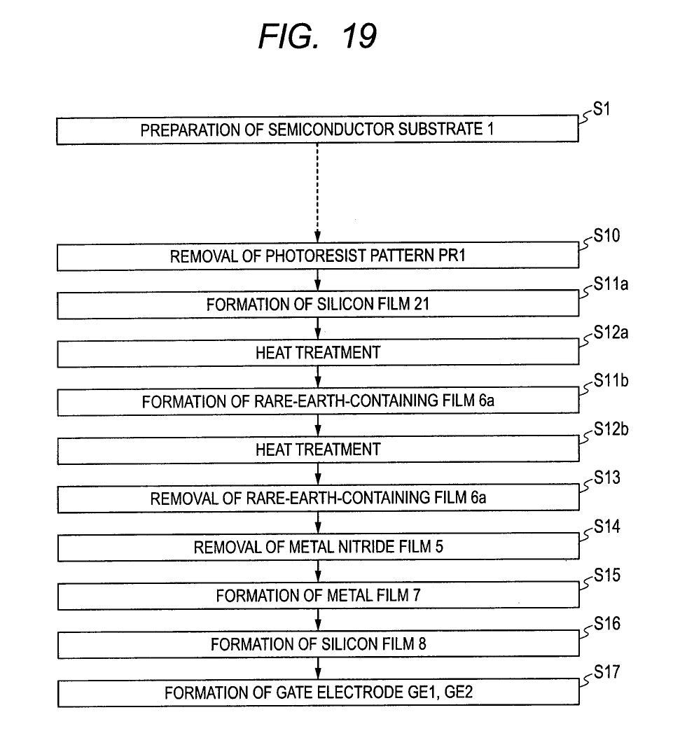

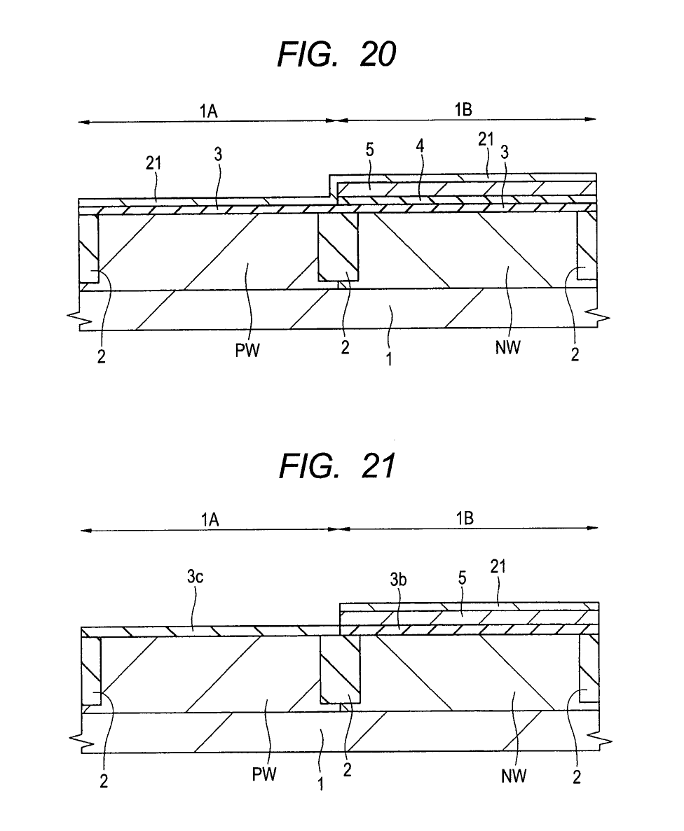

FIG. 19 is a manufacturing process flow chart showing some manufacturing steps of the present embodiment and corresponds to FIG. 1 of Embodiment 1. FIGS. 20 to 25 are fragmentary cross-sectional view of a semiconductor device of the present embodiment during manufacturing steps thereof. To simplify the chart, Steps S2 to Steps S9 are omitted from FIG. 19.

The manufacturing steps of the present embodiment until removal of the photoresist pattern PR1 in Step S10 are similar to those of Embodiment 1. Description on them are therefore omitted and steps after Step S10, that is, steps after removal of the photoresist pattern PR1 in Step S10 will next be described.

After formation of the structure illustrated in FIG. 8 by carrying out similar steps to Steps S1 to S10 of Embodiment 1, a silicon film (silicon layer) 21 is formed as a silicon-containing layer (a layer containing Si) over the main surface of the semiconductor substrate 1 as illustrated in FIG. 20 (Step S11a of FIG. 19).

Since when etching is performed in Steps S8 and S9, the metal nitride film 5 and the Al-containing film 4 are removed from the nMIS formation region 1A, while leaving the metal nitride film 5 and the Al-containing film 4 in the pMIS formation region 1B, the silicon film 21 is formed over the Hf-containing insulating film 3 in the nMIS formation region 1A and over the metal nitride film 5 in the pMIS formation region 1B in Step S11a. The silicon film 21 is therefore in contact with the Hf-containing insulating film 3 in the nMIS formation region 1A, while in the pMIS formation region 1B, the silicon film 21 is not in contact with the Al-containing film 4 (and the Hf-containing insulating film 3) because they have therebetween the metal nitride film 5. The silicon film 21 can be formed by sputtering or the like and its thickness can be set, for example, at from about 0.2 nm to 1 nm.

Then, the resulting semiconductor substrate 1 is heat treated (Step S12a of FIG. 19). The heat treatment in Step S12a can be performed in an inert gas atmosphere while controlling the heat treatment temperature to fall within a range of preferably from 600° C. to 1000° C. By the heat treatment in Step S12a, the Hf-containing insulating film 3 is reacted with the silicon film 21 in the nMIS formation region 1A. Described specifically, in the heat treatment in Step S12a, since the silicon film 21 is in contact with the Hf-containing insulating film 3 in the nMIS formation region 1A, they react with each other to introduce (diffuse) Si configuring the silicon film 21 into the Hf-containing insulating film 3.

By the heat treatment in Step S12a, the silicon film 21 and the Hf-containing insulating film 3 react with each other (are mixed) in the nMIS formation region 1A to form the Hf-containing insulating film 3c as illustrated in FIG. 21. In other words, in the nMIS formation region 1A, Si of the silicon film 21 is introduced into the Hf-containing insulating film 3, whereby the Hf-containing insulating film 3 becomes the Hf-containing insulating film 3c. The Hf-containing insulating film 3c is made of an insulating material containing Hf (hafnium), Si (silicon), and O (oxygen). When the Hf-containing insulating film 3 is an HfON film, the Hf-containing insulating film 3c is an HfSiON film (hafnium silicon oxynitride film), while when the Hf-containing insulating film 3 is an HfO film (typically, an HfO₂ film), the Hf-containing insulating film 3c is an HfSiO film (hafnium silicate film).

In the pMIS formation region 1B, the silicon film 21 is not in contact with the Al-containing film 4 (and the Hf-containing insulating film 3) because they have therebetween the metal nitride film 5. In the heat treatment in Step S12a, the Al-containing film 4 and the Hf-containing insulating film 3 do not react with the silicon film 21 and Si configuring the silicon film 21 is not introduced (diffused) into the Hf-containing insulating film 3 in the pMIS formation region 1B.

In the pMIS formation region 1B, the Hf-containing insulating film 3b is formed by the heat treatment in Step S12a to cause a reaction between the Hf-containing insulating film 3 and the Al-containing film 4. The description on it is however omitted because it is similar to the heat treatment in Step S12 in Embodiment 1 for causing a reaction between the Hf-containing insulating film 3 and the Al-containing film 4 to form the Hf-containing insulating film 3b.

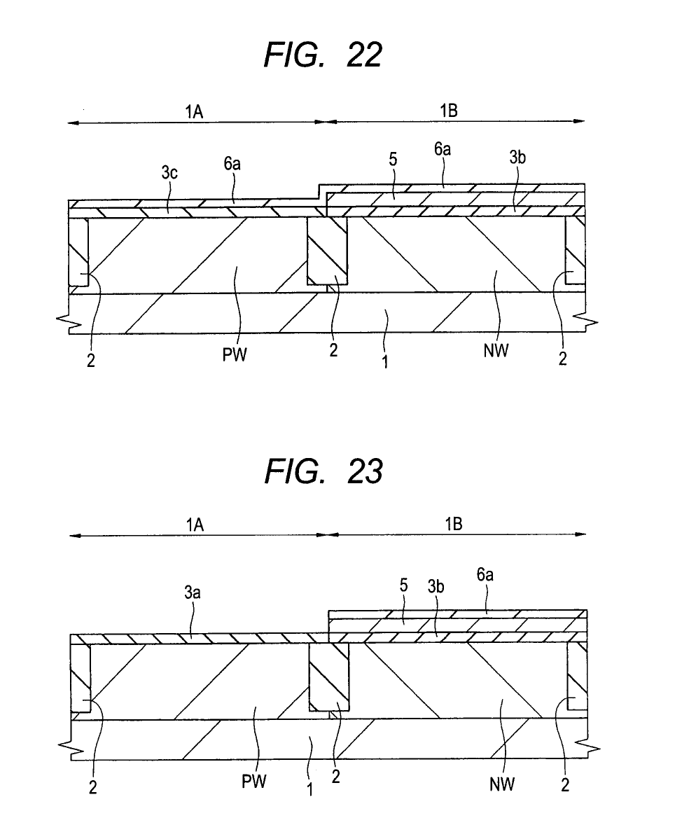

As illustrated in FIG. 22, a rare-earth-containing film (rare-earth-containing layer) 6a is formed over the main surface of the semiconductor substrate 1 (Step S11b of FIG. 19). In Step S11b, the rare-earth-containing film 6a is formed over the Hf-containing insulating film 3c in the nMIS formation region 1A and over the metal nitride film 5 in the pMIS formation region 1B.

After the heat treatment in Step S12a but prior to the formation of the rare-earth-containing film 6a in Step S11b, it is preferred to remove a portion of the silicon film 21, which has remained unreacted in the heat treatment in Step S12a (unreacted silicon film 21), by wet etching or the like. In this case, since the silicon film 21 which has remained over the metal nitride film 5 in the pMIS formation region 1B is removed, the rare-earth-containing film 6a is formed contiguous onto the metal nitride film 5 in the pMIS formation region 1B (FIG. 22 shows this case). As another embodiment, the formation of the rare-earth-containing film 6a in Step S11b may be carried out without carrying out removal of the unreacted silicon film 21 after the heat treatment in Step S12a. In this case, the silicon film 21 has remained over the metal nitride film 5 in the pMIS formation region 1B so that the rare-earth-containing film 6a is formed over the silicon film 21 over the metal nitride film 5 in the pMIS formation region 1B.

The rare-earth-containing film 6a contains a rare earth element, particularly preferably La (lanthanum). In Embodiment 1, a rare earth element contained in the rare-earth-containing film 6 is expressed as Ln. Also in this embodiment, a rare earth element contained in the rare-earth-containing film 6a is expressed as Ln. However, the rare-earth-containing film 6a in this embodiment is not required to contain Si (silicon), different from the rare-earth-containing film 6 in Embodiment 1. This is because Si has already been introduced into the Hf-containing insulating film 3c in the nMIS formation region 1A so that it is not necessary to introduce Si into the Hf-containing insulating film 3c from the rare-earth-containing film 6a. The rare-earth-containing film 6a is preferably a rare earth oxide film (oxidized rare earth film), particularly preferably a lanthanum oxide film (a typical lanthanum oxide is La₂O₃). The rare-earth-containing film 6a can be formed by sputtering, ALD, or the like method and its thickness (deposited thickness) can be set at from about 0.2 nm to 1 nm.

The resulting semiconductor substrate 1 is then heat treated (Step S12b of FIG. 19). The heat treatment in Steps S12b can be performed in an inert gas atmosphere while setting a heat treatment temperature preferably within a range of from 600° C. to 1000° C. By the heat treatment in Step S12b, the Hf-containing insulating film 3c is reacted with the rare-earth-containing film 6a in the nMIS formation region 1A.

By the heat treatment in Step S12b, the rare-earth-containing film 6a and the Hf-containing insulating film 3c are reacted (mixed) to form the Hf-containing insulating film 3a in the nMIS formation region 1A as illustrated in FIG. 23. Described specifically, in the nMIS formation region 1A, the rare earth element Ln of the rare-earth-containing film 6a is introduced into the Hf-containing insulating film 3c, whereby the Hf-containing insulating film 3c becomes the Hf-containing insulating film 3a.

The Hf-containing insulating film 3a is, similar to that of Embodiment 1, made of an insulating material containing Hf (hafnium), a rare earth element Ln (particularly preferably, Ln=La), Si (silicon), and O (oxygen). The rare earth element Ln contained in the Hf-containing insulating film 3a is similar to the rare earth element Ln contained in the rare-earth-containing film 6a. When the Hf-containing insulating film 3 is an HfON film, the Hf-containing insulating film 3c is an HfSiON film and the Hf-containing insulating film 3a is an HfLnSiON film (an HfLaSiON film when Ln=La). When the Hf-containing insulating film 3 is an HfO film (typically, an HfO₂ film), the Hf-containing insulating film 3c is an HfSiO film and the Hf-containing insulating film 3a is an HfLnSiO film (an HfLaSiO film when Ln=La).

Since in the pMIS formation region 1B, the rare-earth-containing film 6a and the Hf-containing insulating film 3b have therebetween the metal nitride film 5, the heat treatment in Step S12b does not cause a reaction between the rare-earth-containing film 6a and the Hf-containing insulating film 3b. The rare earth element Ln configuring the rare-earth-containing film 6a is therefore not introduced (diffused) into the Hf-containing insulating film 3b in the pMIS formation region 1B.

In the pMIS formation region 1B, the heat treatment in Step S12a enables to form the Hf-containing insulating film 3b and the heat treatment in Step S12b also contributes to the formation of the Hf-containing insulating film 3b. Even when an unreacted portion of the Al-containing film 4 remains over the Hf-containing insulating film 3b in the pMIS formation region 1B after the heat treatment in Step S12a, the Al-containing film 4 (unreacted portion of the Al-containing film 4) which has remained unreacted with the Hf-containing insulating film 3 can react with the Hf-containing insulating film 3b in the pMIS formation region 1B further in the heat treatment in Step S12b. Accordingly, in the present embodiment, the Hf-containing insulating film 3b in the pMIS formation region 1B is formed by either one or both of the heat treatment in Steps S12a and heat treatment in Step S12b.

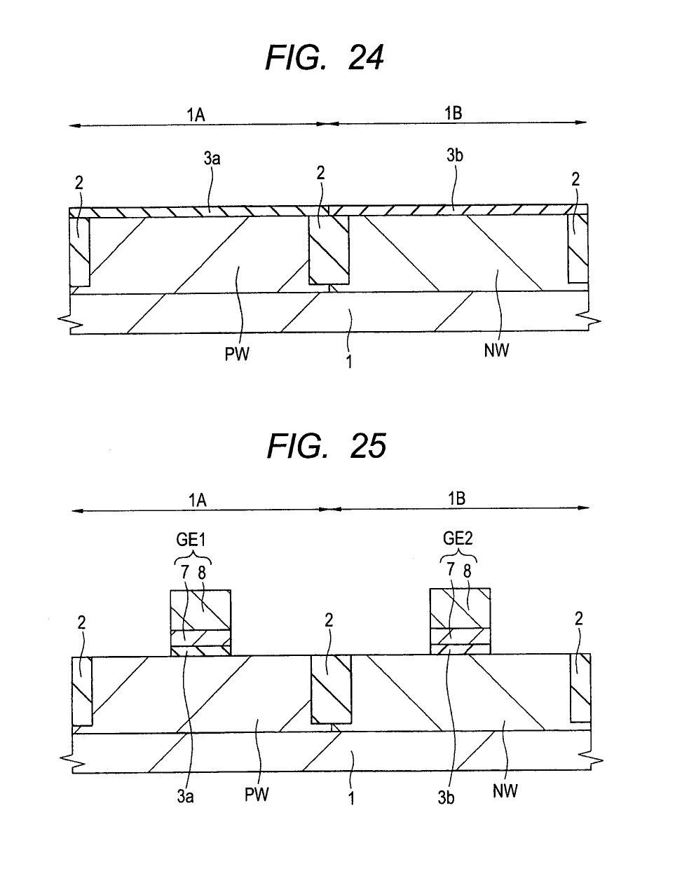

Then, as illustrated in FIG. 24, the rare-earth-containing film 6a (unreacted rare-earth-containing film 6a) which has remained unreacted in the heat treatment in Step S12b is removed by etching (preferably, wet etching) (Step S13 of FIG. 19). Then, the metal nitride film 5 which has been formed in the pMIS formation region 1B is removed by etching (preferably, wet etching) (Step S14 of FIG. 19). As a result, the Hf-containing insulating film 3a is exposed from the nMIS formation region 1A, while the Hf-containing insulating film 3b is exposed from the pMIS formation region 1B.

By the heat treatment in Step S12b, the surface layer portion of the metal nitride film 5 sometimes reacts with the rare-earth-containing film 6a. When formation of the rare-earth-containing film 6a in Step S11b is performed without carrying out removal of the unreacted portion of the silicon film 21 after the heat treatment in Step S12a, the heat treatment in Step S12b may cause a reaction between the silicon film 21 and the rare-earth-containing film 6a over the metal nitride film 5 in the pMIS formation region 1B or a reaction between the surface layer portion of the metal nitride film 5 and the silicon film 21. Even in such a case, a reaction product between the surface layer portion of the metal nitride film 5 and the rare-earth-containing film 6a or the silicon film 21 or a reaction product between the rare-earth-containing film 6a and the silicon film 21 in the pMIS formation region 1B can be removed by etching in Step S13 or Step S14 or wet etching performed between Step S13 and Step S14. This means that the metal nitride film 5 and the structure thereabove in the pMIS formation region 1B can be removed completely when the metal nitride film 5 is removed in Step S14.

Steps thereafter are similar to those of Embodiment 1. Described specifically, similar to Embodiment 1, gate electrodes GE1 and GE2 are formed as illustrated in FIG. 25 by forming a metal film 7 over the main surface of the semiconductor substrate 1 (Step S15 of FIG. 19), forming a silicon film 8 over the metal film 7 (Step S16 of FIG. 19), and patterning a film stack of the silicon film 8 and the metal film 7 (Step S17 of FIG. 19).

In the present embodiment, similar to Embodiment 1, the gate electrode GE1 is formed over the Hf-containing insulating film 3a in the nMIS formation region 1A and the gate electrode GE2 is formed over the Hf-containing insulating film 3b in the pMIS formation region 1B. Described specifically, the gate electrode GE1 made of the metal film 7 and the silicon film 8 over the metal film 7 is formed over the surface of the p-type well PW in the nMIS formation region 1A via the Hf-containing insulating film 3a serving as a gate insulating film; and the gate electrode GE2 made of the metal film 7 and the silicon film 8 over the metal film 7 is formed over the surface of the n-type well NW in the pMIS formation region 1B via the Hf-containing insulating film 3b serving as a gate insulating film.

Steps after formation of the gate electrodes GE1 and GE2 are similar to those of Embodiment 1 so that they are not illustrated here and description on them is omitted. The configuration of the semiconductor device thus manufactured is almost similar to that of Embodiment 1 so that description on it is omitted herein.

In the present embodiment, the following advantage is available in addition to the advantage obtained in Embodiment 1.

In the present embodiment, after the Hf-containing insulating film 3c containing also Si is formed by heat treating the Hf-containing insulating film 3 and the silicon film 21 in the nMIS formation region 1A in Step S12a to cause a reaction therebetween, the resulting Hf-containing insulating film 3c and the rare-earth-containing film 6a are heat treated in Step S12b to cause a reaction therebetween to form the Hf-containing insulating film 3a. Since a binding power between a rare earth element Ln (particularly La) and Si is stronger than a binding power between a rare earth element Ln (particularly, La) and Hf, diffusion of the rare earth element Ln (particularly La) tends to be suppressed in the Hf-based gate insulating film (for example, an HfON film or an HfO film) which does not contain Si. On the other hand, the rare earth element Ln (particularly, La) is easily diffused in an Si-containing Hf-based gate insulating film (preferably, an HfSiON film or an HfSiO film) in a substrate direction. It is therefore possible to sufficiently diffuse the rare earth element Ln (particularly La) of the rare-earth-containing film 6a in the Hf-containing insulating film 3a in a substrate direction by, as in the present embodiment, forming the Hf-containing insulating film 3c (preferably, an HfSiON film or an HfSiO film) containing also Si first in the nMIS formation region 1A and then carrying out the heat treatment in Step S12b to react the Hf-containing insulating film 3c with the rare-earth-containing film 6a. In order to minimize the threshold value (absolute value thereof) of the re-channel MISFET Qn to be formed in the nMIS formation region 1A, it is preferred that the rare earth element Ln (particularly, La) is diffused sufficiently in the Hf-containing insulating film 3a in a substrate direction. In the present embodiment, the rare earth element Ln (particularly, La) can be diffused fully in the resulting Hf-containing insulating film 3a in a substrate direction so that it becomes possible to improve a reduction effect of the threshold value of the n-channel MISFET Qn, which has been produced by the introduction of the rare earth element Ln (particularly, La) into the Hf-based gate insulating film, and thereby reduce the threshold value (absolute value thereof) of the n-channel MISFET Qn further. The CMISFET equipped with the n-channel MISFET Qn and the p-channel MISFET Qp can have further improved characteristics and the semiconductor device can have further improved performance.

In Embodiment 1, the Hf-containing insulating film 3a is formed by heat treating the Hf-containing insulating film 3 and the rare-earth-containing film 6 in the nMIS formation region 1A to cause a reaction therebetween in Step S12 so that the number of manufacturing steps of the semiconductor device can be reduced. As a result, the semiconductor device can have improved performance while decreasing the manufacturing time or manufacturing cost of it. Further, the throughput of the semiconductor device can be improved.

### Embodiment 3

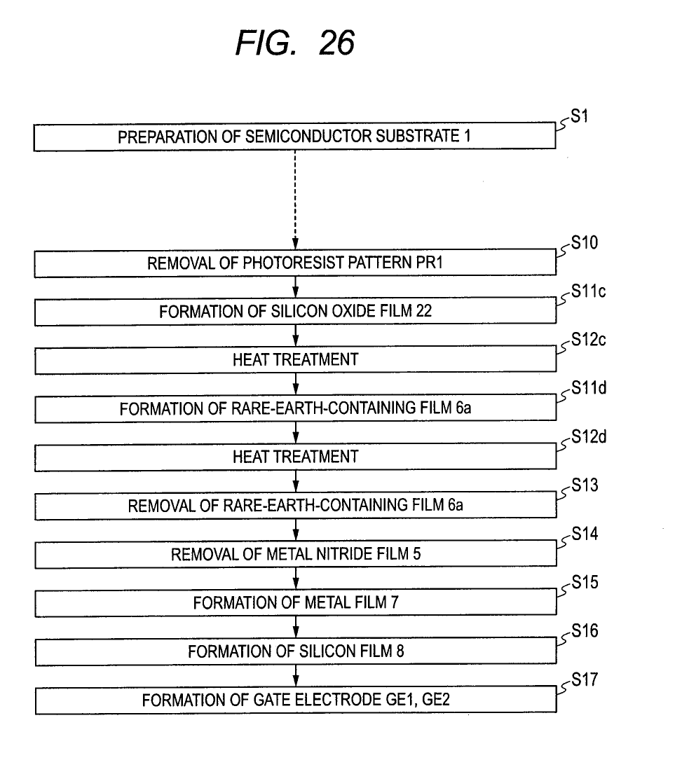

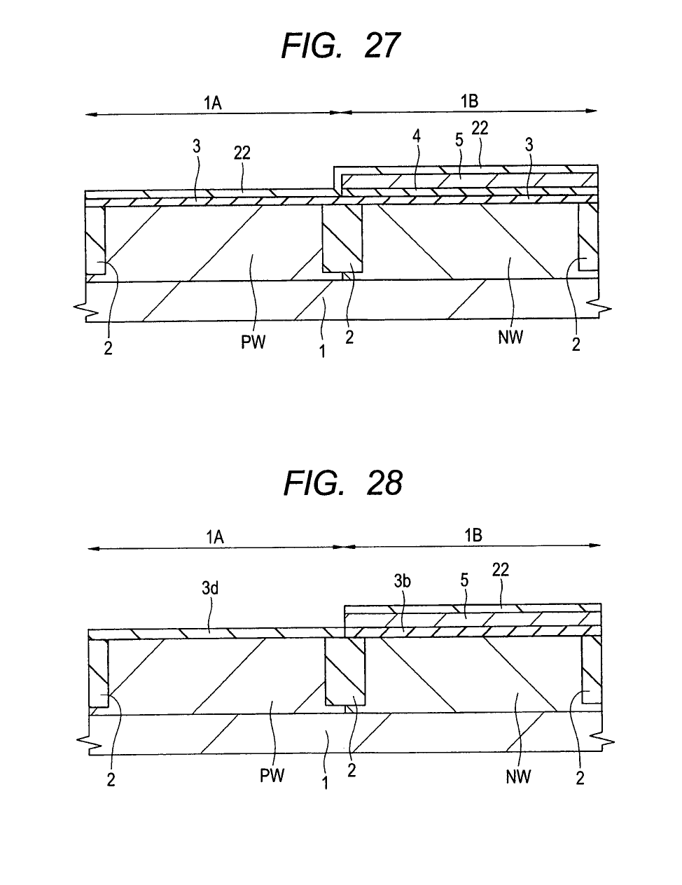

FIG. 26 is a manufacturing process flow chart showing some manufacturing steps of the present embodiment and it corresponds to FIG. 1 of Embodiment 1. FIGS. 27 to 32 are fragmentary cross-sectional views illustrating a semiconductor device of the present embodiment during the manufacturing steps thereof.

The manufacturing steps of the present embodiment until removal of the photoresist pattern PR1 in Step S10 are similar to those of Embodiment 1. Description on them are therefore omitted and steps after Step S10, that is, steps after removal of the photoresist pattern PR1 in step S10 will next be described.

After formation of the structure illustrated in FIG. 8 by the steps similar to Steps S1 to S10 in Embodiment 1, a silicon oxide film (silicon oxide layer) 22 is formed as a silicon-containing layer (a layer containing silicon) over the main surface of the semiconductor substrate 1 as illustrated in FIG. 27 (Step S11c of FIG. 26).

In the etching step in Steps S8 and S9, the metal nitride film 5 and the Al-containing film 4 are removed from the nMIS formation region 1A and at the same time, the metal nitride film 5 and the Al-containing film 4 are left in the pMIS formation region 1B. In Step S11c, therefore, the silicon oxide film 22 is formed over the Hf-containing insulating film 3 in the nMIS formation region 1A, while it is formed over the metal nitride film 5 in the pMIS formation region 1B. The silicon oxide film 22 is therefore in contact with the Hf-containing insulating film 3 in the nMIS formation region 1A but in the pMIS formation region 1B, the silicon oxide film 22 and the Al-containing film 4 (and the Hf-containing insulating film 3) are not in contact with each other because they have therebetween the metal nitride film 5. The silicon oxide film 22 can be formed by sputtering or the like and its thickness can be set at, for example, from about 0.2 nm to 1 nm.

The resulting substrate 1 is then heat treated (Step S12c of FIG. 26). The heat treatment in Step S12c can be carried out in an inert gas atmosphere while setting a heat treatment temperature at preferably from 600° C. to 1000° C. By the heat treatment in Step S12c, the Hf-containing insulating film 3 is reacted with the silicon oxide film 22 in the nMIS formation region 1A. This means that in the heat treatment in Step S12c, since the silicon oxide film 22 and the Hf-containing insulating film 3 are in contact with each other, they react in the nMIS formation region 1A and silicon (Si) and oxygen (O) configuring the silicon oxide film 22 are introduced (diffused) into the Hf-containing insulating film 3.

By the heat treatment in Step S12c, the silicon oxide film 22 and the Hf-containing insulating film 3 react with each other (are mixed) to form the Hf-containing insulating film 3d as illustrated in FIG. 28. In other words, in the nMIS formation region 1A, silicon (Si) and oxygen (O) of the silicon oxide film 22 are introduced into the Hf-containing insulating film 3, whereby the Hf-containing insulating film 3 becomes an Hf-containing insulating film 3d. The Hf-containing insulating film 3d is made of an insulating material containing Hf (hafnium), Si (silicon), and O (oxygen). When the Hf-containing insulating film 3 is an HfON film, the Hf-containing insulating film 3d is an HfSiON film (hafnium silicon oxynitride film), while when the Hf-containing insulating film 3 is an HfO film (typically, an HfO₂ film), the Hf-containing insulating film 3d is an HfSiO film (hafnium silicate film).

In the pMIS formation region 1B, the silicon oxide film 22 is not in contact with the Al-containing film 4 because they have therebetween the metal nitride film 5. In the heat treatment in Step S12c, the Al-containing film 4 and the Hf-containing insulating film 3 do not react with the silicon oxide film 22 and Si configuring the silicon oxide film 22 is not introduced (diffused) into the Hf-containing insulating film 3 in the pMIS formation region 1B.

In the pMIS formation region 1B, an Hf-containing insulating film 3b is formed by the heat treatment in Step S12c to cause a reaction between the Hf-containing insulating film 3 and the Al-containing film 4. The description on it is however omitted because it is similar to the heat treatment in Step S12 in Embodiment 1 for causing a reaction between the Hf-containing insulating film 3 and the Al-containing film 4 to form the Hf-containing insulating film 3b.

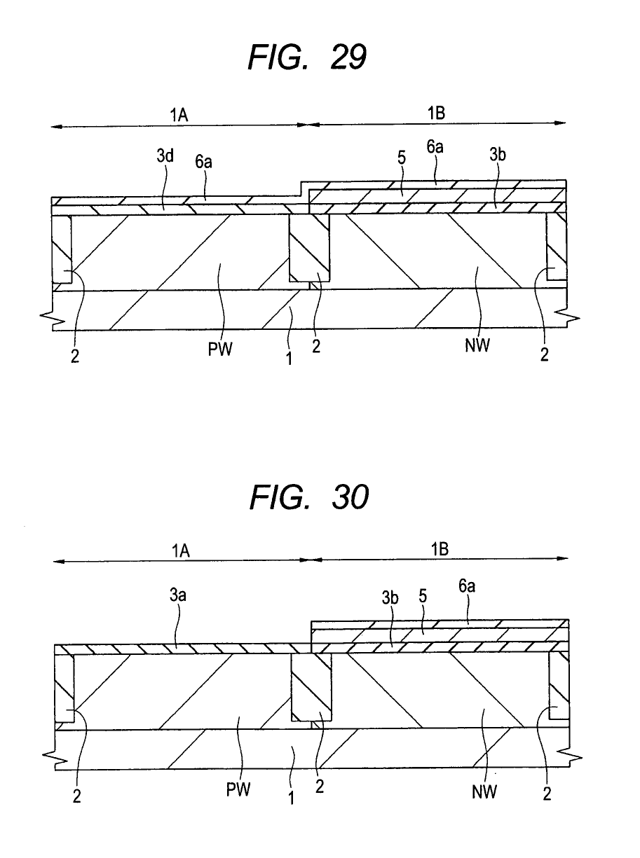

As illustrated in FIG. 29, a rare-earth-containing film 6a is formed over the main surface of the semiconductor substrate 1 (Step Slid of FIG. 26). In Step Slid, the rare-earth-containing film 6a is formed over the Hf-containing insulating film 3d in the nMIS formation region 1A and it is formed over the metal nitride film 5 in the pMIS formation region 1B. The configuration, film forming method, and thickness of the rare-earth-containing film 6a are similar to those in Embodiment 2 so that description on them will be omitted here.

After the heat treatment in Step S12c but prior to the formation of the rare-earth-containing film 6a in Step S11d, it is preferred to remove a portion of the silicon oxide film 22 which has unreacted in the heat treatment in Step S12c (unreacted silicon oxide film 22) by wet etching or the like. In this case, since the silicon oxide film 22 which has remained over the metal nitride film 5 in the pMIS formation region 1B is removed, the rare-earth-containing film 6a is contiguous onto the metal nitride film 5 in the pMIS formation region 1B (FIG. 29 shows this case). As another embodiment, after the heat treatment in Step S12c, the formation of the rare-earth-containing film 6a in Step Slid may be carried out without carrying out a step of removing the unreacted silicon oxide film 22. In this case, the silicon oxide film 22 has remained over the metal nitride film 5 in the pMIS formation region 1B so that the rare-earth-containing film 6a is formed over the silicon oxide film 22 over the metal nitride film 5 in the pMIS formation region 1B.

The resulting semiconductor substrate 1 is then heat treated (Step S12d of FIG. 26). The heat treatment in Steps S12d can be performed in an inert gas atmosphere while setting a heat treatment temperature to fall within a range of from 600° C. to 1000° C. By the heat treatment in Step S12d, the Hf-containing insulating film 3d is reacted with the rare-earth-containing film 6a in the nMIS formation region 1A.

By the heat treatment in Step S12d, the rare-earth-containing film 6a and the Hf-containing insulating film 3d are reacted (mixed) to form the Hf-containing insulating film 3a in the nMIS formation region 1A as illustrated in FIG. 30. Described specifically, in the nMIS formation region 1A, the rare earth element Ln of the rare-earth-containing film 6a is introduced into the Hf-containing insulating film 3d and the Hf-containing insulating film 3d becomes the Hf-containing insulating film 3a.

The Hf-containing insulating film 3a is, similar to that of Embodiment 1, made of an insulating material containing Hf (hafnium), a rare earth element Ln (particularly preferably, Ln=La), Si (silicon), and O (oxygen). The rare earth element Ln contained in the Hf-containing insulating film 3a is similar to the rare earth element Ln contained in the rare-earth-containing film 6a. When the Hf-containing insulating film 3 is an HfON film, the Hf-containing insulating film 3d is an HfSiON film and the Hf-containing insulating film 3a is an HfLnSiON film (an HfLaSiON film when Ln=La). When the Hf-containing insulating film 3 is an HfO film (typically, an HfO₂ film), the Hf-containing insulating film 3d is an HfSiO film and the Hf-containing insulating film 3a is an HfLnSiO film (an HfLaSiO film when Ln=La).

Since in the pMIS formation region 1B, the rare-earth-containing film 6a and the Hf-containing insulating film 3b have therebetween the metal nitride film 5, the heat treatment in Step S12d does not cause a reaction between the rare-earth-containing film 6a and the Hf-containing insulating film 3b. The rare earth element Ln configuring the rare-earth-containing film 6a is not introduced (diffused) into the Hf-containing insulating film 3b in the pMIS formation region 1B.

In the pMIS formation region 1B, the heat treatment in Step S12c enables to form the Hf-containing insulating film 3b and the heat treatment in Step S12d also contributes to the formation of the Hf-containing insulating film 3b. Even when an unreacted portion of the Al-containing film 4 remains over the Hf-containing insulating film 3b in the pMIS formation region 1B after the heat treatment in Step S12c, the Al-containing film 4 (unreacted portion of the Al-containing film 4) which has remained unreacted with the Hf-containing insulating film 3 can react with the Hf-containing insulating film 3b in the pMIS formation region 1B further in the heat treatment in Step S12d. Accordingly, in the present embodiment, the Hf-containing insulating film 3b in the pMIS formation region 1B is formed by either one or both of the heat treatment in Step S12c and heat treatment in Step S12d.

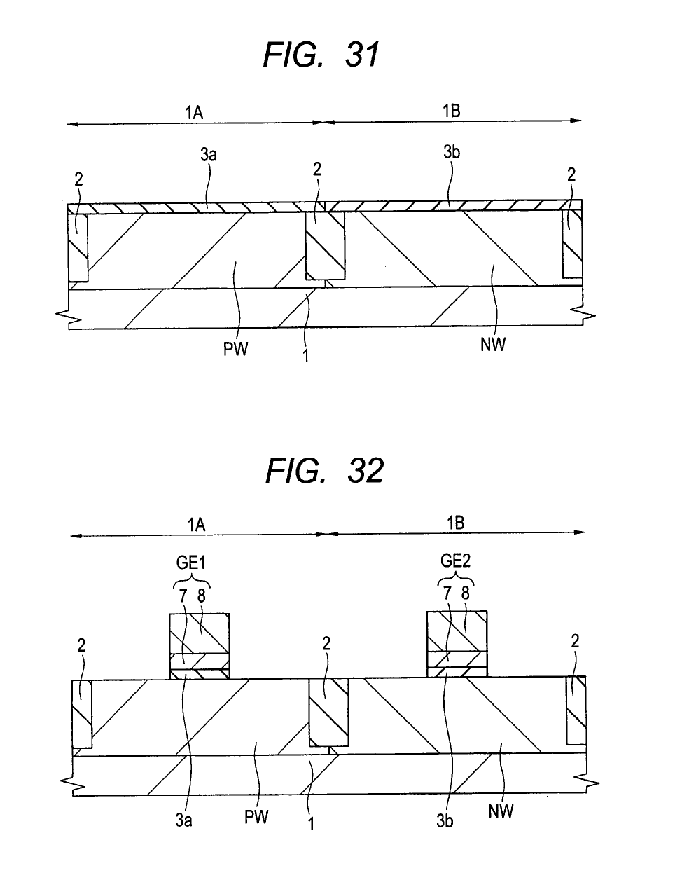

Then, as illustrated in FIG. 31, the rare-earth-containing film 6a (an unreacted portion of the rare-earth-containing film 6a) which has remained unreacted in the heat treatment in Step S12d is removed by etching (preferably, wet etching) (Step S13 of FIG. 26). Then, the metal nitride film 5 which has been formed in the pMIS formation region 1B is removed by etching (preferably, wet etching) (Step S14 of FIG. 26). As a result, the Hf-containing insulating film 3a is exposed from the nMIS formation region 1A, while the Hf-containing insulating film 3b is exposed from the pMIS formation region 1B.

By the heat treatment in Step S12b, a surface layer portion of the metal nitride film 5 sometimes reacts with the rare-earth-containing film 6a. When the step of forming the rare-earth-containing film 6a in Step S11d is performed without carrying out a step of removing the unreacted portion of the silicon oxide film 22 after the heat treatment in Step S12c, the heat treatment in Step S12d may cause, in the pMIS formation region 1B, a reaction between the silicon oxide film 22 over the metal nitride film 5 and the rare-earth-containing film 6a or a reaction between the surface layer portion of the metal nitride film 5 and the silicon oxide film 22. Even in such a case, a reaction product between the surface layer portion of the metal nitride film 5 and the rare-earth-containing film 6a or the silicon oxide film 22 or a reaction product between the rare-earth-containing film 6a and the silicon oxide film 22 in the pMIS formation region 1B can be removed by etching in Step S13 or Step S14 or wet etching performed between Step S13 and Step S14. This means that the metal nitride film 5 and the structure thereabove in the pMIS formation region 1B can be removed completely after removal of the metal nitride film 5 in Step S14.

Steps thereafter are similar to those of Embodiment 1. Described specifically, similar to Embodiment 1, gate electrodes GE1 and GE2 are formed as illustrated in FIG. 32 by forming a metal film 7 over the main surface of the semiconductor substrate 1 (Step S15 of FIG. 26), forming a silicon film 8 over the metal film 7 (Step S16 of FIG. 26), and patterning a film stack of the silicon film 8 and the metal film 7 (Step S17 of FIG. 26).

In the present embodiment, similar to Embodiments 1 and 2, the gate electrode GE1 is formed over the Hf-containing insulating film 3a in the nMIS formation region 1A and the gate electrode GE2 is formed over the Hf-containing insulating film 3b in the pMIS formation region 1B. Described specifically, the gate electrode GE1 made of the metal film 7 and the silicon film 8 over the metal film 7 is formed over the surface of the p-type well PW in the nMIS formation region 1A via the Hf-containing insulating film 3a serving as a gate insulating film; and the gate electrode GE2 made of the metal film 7 and the silicon film 8 over the metal film 7 is formed over the surface of the n-type well NW in the pMIS formation region 1B via the Hf-containing insulating film 3b serving as a gate insulating film.

Steps after formation of the gate electrodes GE1 and GE2 are similar to those of Embodiment 1 or 2 so that they are not illustrated here and description on them is omitted. The configuration of the semiconductor device thus manufactured is almost similar to that of Embodiment 1 so that description on it is omitted.

In the present embodiment, the following advantage is available in addition to the advantage obtained in Embodiment 1.

In the present embodiment, in the nMIS formation region 1A, the heat treatment in Step S12c is carried out to react the Hf-containing insulating film 3 with the silicon oxide film 22 to obtain the Hf-containing insulating film 3d and then the heat treatment in Step S12d is carried out to react the Hf-containing insulating film 3d with the rare-earth-containing film 6a to obtain the Hf-containing insulating film 3a. In the present embodiment similar to Embodiment 1, in the nMIS formation region 1A, the rare earth element Ln (particularly, La) of the rare-earth-containing film 6a can be diffused sufficiently in the Hf-containing insulating film 3a in a substrate direction by forming the Hf-containing insulating film 3d (preferably, an HfSiON film or an HfSiO film) in advance and then carrying out the heat treatment in Step S12d to react the Hf-containing insulating film 3d with the rare-earth-containing film 6a. In the present embodiment similar to Embodiment 1, since the rare earth element (particularly, La) can be diffused sufficiently in the resulting Hf-containing insulating film 3a in a substrate direction, an effect of reducing the threshold value of the re-channel MISFET Qn produced by the introduction of a rare earth element Ln into the Hf-based gate insulating film can be improved further, making it possible to reduce the threshold value (absolute value thereof) of the n-channel MISFET Qn further. As a result, the CMISFET equipped with the n-channel MISFET Qn and the p-channel MISFET Qp can have further improved characteristics and the semiconductor device can have further improved performance.

Further, in the present embodiment, since the Hf-containing insulating film 3 and the silicon oxide film 22 are reacted by heat treatment in Step S12c to form the Hf-containing insulating film 3d, the Hf-containing insulating film 3d (preferably, an HfSiON film or an HfSiO film) can be formed by introducing not only silicon (Si) but also oxygen (O) into the Hf-containing insulating film 3 from the silicon oxide film 22. This makes it possible to compensate for oxygen defects of the Hf-based gate insulating film and improve the TDDB life further.

In Embodiment 1, since the Hf-containing insulating film 3a is formed by carrying out heat treatment in Step S12 to cause a reaction between the Hf-containing insulating film 3 and the rare-earth-containing film 6 in the nMIS formation region 1A, the number of manufacturing steps of the semiconductor device can be reduced. As a result, the semiconductor device can have improved performance while suppressing the manufacturing time or manufacturing cost of it. Further, the throughput of the semiconductor device can be improved.

The invention made by the present inventors was described above specifically based on some embodiments. It is needless to say that the invention is not limited to the above embodiments and can be changed without departing from the scope thereof.

The invention is effective when applied to a semiconductor device and a manufacturing technology thereof.

What is claimed is:

1. A semiconductor device comprising an n-channel first MISFET in a first region of a semiconductor substrate and a p-channel second MISFET in a second region of the semiconductor substrate,
wherein the first MISFET has a first metal gate electrode formed over the semiconductor substrate via a first gate insulating film,
wherein the second MISFET has a second metal gate electrode formed over the semiconductor substrate via a second gate insulating film,
wherein the first gate insulating film has an insulating material containing, as a main component thereof, hafnium, a rare earth element, silicon, and oxygen, and
wherein the second gate insulating film has an insulating material containing, as a main component thereof, hafnium, aluminum, and oxygen and not containing, as a main component thereof, silicon.

2. The semiconductor device according to claim 1,
wherein the first gate insulating film is an insulating material film having hafnium, a rare earth element, silicon, oxygen, and nitrogen or an insulating material film having hafnium, a rare earth element, silicon, and oxygen, and
wherein the second gate insulating film is an insulating material film having hafnium, aluminum, oxygen, and nitrogen or an insulating material film having hafnium, aluminum, and oxygen.

3. The semiconductor device according to claim 2,
wherein the rare earth element contained in the first gate insulating film is lanthanum.

4. The semiconductor device according to claim 3,
wherein the first and second metal gate electrodes each have a stack structure of a metal film and a silicon film over the metal film.

5. The semiconductor device according to claim 4,
wherein the metal film is a titanium nitride film.

6. A manufacturing method of a semiconductor device comprising an n-channel first MISFET in a first region of a semiconductor substrate and a p-channel second MISFET in a second region of the semiconductor substrate, comprising the steps of:
(a) forming an Hf-containing first insulating film to be used for a gate insulating film of the first and second MISFETs in the first region and the second region of the semiconductor substrate;
(b) after the step (a), forming an Al-containing film over the first insulating film formed in the first region and the second region;
(c) after the step (b), forming a mask layer over the Al-containing film formed in the first region and the second region;
(d) after the step (c), removing the mask layer from the first region and leaving the mask layer in the second region;
(e) after the step (d), removing the Al-containing film from the first region and leaving the Al-containing film in the second region;
(f) after the step (e), forming a rare-earth-containing film containing a rare earth element and silicon over the first insulating film in the first region and the mask layer in the second region;
(g) after the step (f), carrying out heat treatment to cause a reaction between the first insulating film with the rare-earth-containing film in the first region and between the first insulating film with the Al-containing film in the second region;
(h) after the step (g), removing the rare-earth-containing film which has remained unreacted in the step (g);
(i) after the step (h), removing the mask layer;
(j) after the step (i), forming a metal film over the first insulating film in the first region and the second region; and
(k) after the step (j), patterning the metal film to form a first gate electrode for the first MISFET in the first region and a second gate electrode for the second MISFET in the second region.

7. The manufacturing method of a semiconductor device according to claim 6,
wherein the Al-containing film formed in the step (b) is free from silicon.

8. The manufacturing method of a semiconductor device according to claim 7,
wherein the first insulating film is a hafnium oxynitride film or a hafnium oxide film.

9. The manufacturing method of a semiconductor device according to claim 8,
wherein the rare-earth-containing film formed in the step (f) is a rare earth silicate film.

10. The manufacturing method of a semiconductor device according to claim 9,
wherein the rare-earth-containing film formed in the step (f) is a lanthanum silicate film.

11. The manufacturing method of a semiconductor device according to claim 10,
wherein the Al-containing film formed in the step (b) is an aluminum oxide film.

12. The manufacturing method of a semiconductor device according to claim 11,
wherein the mask layer formed in the step (c) is a metal nitride film.

13. The manufacturing method of a semiconductor device according to claim 12, further comprising, after the step (j) but prior to the step (k), the step of:
(j1) forming a silicon film over the metal film,
wherein in the step (k), the metal film and the silicon film over the metal film are patterned to form the first gate electrode in the first region and the second gate electrode in the second region.

14. The manufacturing method of a semiconductor device according to claim 13,
wherein in the step (g), the heat treatment causes a reaction between the first insulating film and the rare-earth-containing film in the first region to form an HfLaSiON film or an HfLaSiO film and a reaction between the first insulating film and the Al-containing film in the second region to form an HfAlON film or an HfAlO film.

15. A manufacturing method of a semiconductor device comprising an n-channel first MISFET in a first region of a semiconductor substrate and a p-channel second MISFET in a second region of the semiconductor substrate, comprising the steps of:
(a) forming an Hf-containing first insulating film to be used for a gate insulating film of the first and second MISFETs in the first region and the second region of the semiconductor substrate;
(b) after the step (a), forming an Al-containing film over the first insulating film formed in the first region and the second region;
(c) after the step (b), forming a mask layer over the Al-containing layer formed in the first region and the second region;
(d) after the step (c), removing the mask layer from the first region and leaving the mask layer in the second region;
(e) after the step (d), removing the Al-containing film from the first region and leaving the Al-containing film in the second region;
(f) after the step (e), forming a silicon-containing layer over the first insulating film in the first region and the mask layer in the second region;
(g) after the step (f), carrying out first heat treatment to cause a reaction between the first insulating film in the first region with the silicon-containing layer and between the first insulating film in the second region with the Al-containing film;
(h) after the step (g), forming a rare-earth-containing film over the first insulating film in the first region and the mask layer in the second region;
(i) after the step (h), carrying out second heat treatment to cause a reaction between the first insulating film in the first region and the rare-earth-containing film;
(j) after the step (i), removing the rare-earth-containing film which has remained unreacted in the step (i);
(k) after the step (j), removing the mask layer;
(l) after the step (k), forming a metal film over the first insulating film in the first region and the second region; and
(m) after the step (l), patterning the metal film to form a first gate electrode for the first MISFET in the first region and a second gate electrode for the second MISFET in the second region.

16. The manufacturing method of a semiconductor device according to claim 15,
wherein the silicon-containing layer is a silicon film or a silicon oxide film.

17. The manufacturing method of a semiconductor device according to claim 16,
wherein the first insulating film is a hafnium oxynitride film or a hafnium oxide film.

18. The manufacturing method of a semiconductor device according to claim 17,
wherein the rare-earth-containing film formed in the step (h) is a rare earth oxide film.

19. The manufacturing method of a semiconductor device according to claim 18,
wherein the rare-earth-containing film formed in the step (h) is a lanthanum oxide film.

20. The manufacturing method of a semiconductor device according to claim 19,
wherein the Al-containing film formed in the step (b) is an aluminum oxide film.

21. The manufacturing method of a semiconductor device according to claim 20,
wherein the mask layer formed in the step (c) is a metal nitride film.

22. The manufacturing method of a semiconductor device according to claim 21, further comprising, after the step (l) but prior to the step (m), the step of:
(l1) forming a silicon film over the metal film,
wherein in the step (m), the metal film and the silicon film over the metal film are patterned to form the first gate electrode in the first region and the second gate electrode in the second region.

23. The manufacturing method of a semiconductor device according to claim 22,
wherein in the step (g), the first heat treatment causes a reaction between the first insulating film and the silicon-containing layer in the first region to form an HfSiON film or an HfSiO film and a reaction between the first insulating film and the Al-containing film in the second region to form an HfAlON film or an HfAlO film, and
wherein in the step (i), the second heat treatment causes a reaction between the HfSiON film or the HfSiO film and the rare-earth-containing film in the first region to form an HfLaSiON film or an HfLaSiO film.
